(19) United States
(12) Patent Application Publication
(10) Pub. No.: US 2010/0117141 A1
(43) Pub. Date: May 13, 2010

(54) Memory cell transistors having limited charge spreading, non-volatile memory devices including such transistors, and methods of formation thereof

(75) Inventors: Dong-woon Shin, Seongnam-si (KR); Young-Kun Park, Suwon-si (KR); Jun-gyu Yang, Seoul (KR); Jae-young Ahn, Seongnam-si (KR); Ki-hyun Hwang, Seongnam-si (KR); Si-young Choi, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/590,641

(22) Filed: Nov. 12, 2009

(30) Foreign Application Priority Data
Nov. 13, 2008 (KR) 10-2008-0112916
Mar. 9, 2009 (KR) 10-2009-0019947

(51) Int. Cl. H01L 27/105; H01L 29/792

(52) U.S. Cl. 257/326; 257/E27.081; 257/E29.309

(57) ABSTRACT

In one aspect, a transistor comprises: a substrate body; a tunnel oxide layer on the body; a charge trapping layer on the tunnel oxide layer; a blocking layer on the charge trapping layer; a control gate on the blocking layer, the control gate having first and second sidewalls, the first and second sidewalls being spaced apart from each other by a first distance; and charge confinement features on the body, the charge confinement features being spaced apart from each other by a second distance that is greater than or substantially equal to the first distance, the charge confinement features suppressing or preventing migration of charge present in the charge trapping layer.

### RELATED APPLICATIONS

This application claims priority under 35 U.S.C. 119 to Korean Patent Application No. 10-2008-0112916, filed on Nov. 13, 2008, and Korean Patent Application No. 10-2009-0019947, filed on Mar. 9, 2009, the content of each being incorporated herein by reference, in its entirety.

### BACKGROUND

With the continued emphasis on highly integrated electronic devices, there is an ongoing need for semiconductor memory devices that operate at higher speed and lower power and that have increased device density. To accomplish this, devices with aggressive scaling and multiple-layered devices with transistor cells arranged in horizontal and vertical arrays have been under development.

As devices continue to become increasingly scaled down in size, charge migration between neighboring cells becomes a more significant issue. With charge migration, charge present in a charge trapping layer of a cell of a non-volatile memory device can migrate, or spread, in a lateral direction across the charge trapping layer to other cells, or to other regions of the charge-trapping layer. As a result, information stored in the memory cell can be inadvertently changed, compromising the reliability and operational integrity of the resulting memory device.

### SUMMARY

Embodiments of the present invention are directed to memory transistors such as memory cell transistors and non-volatile memory devices including such transistors that address and overcome the limitations of the conventional approaches. Further, embodiments of the present invention are directed to methods of forming such transistors and memory devices that address and overcome such limitations.

In particular, embodiments of the present invention mitigate or eliminate charge migration between neighboring cells or charge migration to other regions of the charge trapping layer. In one embodiment, charge confinement feature, or a layer comprising charge confinement material, are provided that limit or prevent such charge migration of charge present in the charge trapping layer.

In one aspect, a transistor comprises: a substrate body; a tunnel oxide layer on the body; a charge trapping layer on the tunnel oxide layer; a blocking layer on the charge trapping layer; a control gate on the blocking layer, the control gate having first and second sidewalls, the first and second sidewalls being spaced apart from each other by a first distance; and charge confinement features on the body, the charge confinement features being spaced apart from each other by a second distance that is greater than or substantially equal to the first distance, the charge confinement features suppressing or preventing migration of charge present in the charge trapping layer.

In one embodiment, the charge confinement features are further on the charge trapping layer.

In another embodiment, the charge confinement features comprise a material that contains negative charge.

In another embodiment, the material comprises metal nitride.

In another embodiment, the material comprises aluminum nitride or aluminum oxynitride whose nitrogen content is richer than oxygen.

In another embodiment, the charge confinement features comprise a charge trapping material that can trap negative charge.

In another embodiment, the charge trapping material comprises silicon nitride or silicon oxynitride whose nitrogen content is richer than oxygen.

In another embodiment, the charge confinement features are further on the charge trapping layer and are positioned in the blocking layer, the charge confinement features having sidewalls that are in contact with the blocking layer.

In another embodiment, the charge confinement features are further on the charge trapping layer and positioned in the blocking layer, the charge confinement features having inner sidewalls that are in contact with the blocking layer and having sidewalls that are not in contact with the blocking layer.

In another embodiment, the transistor further comprises insulative sidewall spacers at the first and second sidewalls of the control gate, wherein the charge confinement features are further on the charge trapping layer and are positioned in the blocking layer below the sidewall spacers.

In another embodiment, the charge confinement features comprise sidewall spacers at the first and second sidewalls of the control gate and on the blocking layer.

In another embodiment, the charge confinement features are further on the charge trapping layer and comprise a charge confinement layer pattern positioned adjacent the first and second sidewalls of the control gate and on the blocking layer.

In another embodiment, the charge confinement features comprise a film that covers the blocking layer and the first and second sidewalls of the control gate.

In another embodiment, the transistor further comprises insulative sidewall spacers at the sidewalls of the control gate, wherein the charge confinement features are further on the charge trapping layer and positioned on the blocking layer and wherein lower portions of the sidewall spacers are spaced apart from each other by a third distance that is equal to or less than the second distance.

In another embodiment, the body of semiconductor material comprises a vertical channel comprising semiconductor material.

In another aspect, a memory device comprises: a first memory cell and a second memory cell on a common body of semiconductor material, the first and second memory cells each comprising: a tunnel oxide layer on the body; a charge trapping layer on the tunnel oxide layer, a blocking layer on the charge trapping layer; and a control gate on the blocking layer. The control gate of the first memory cell and the control gate of the second memory cell have facing opposed sidewalls. The device further comprises a charge confinement feature on the charge trapping layer having a horizontal position that is between horizontal positions of the opposed sidewalls of the control gates, the charge confinement feature limiting migration of charge present in the charge trapping layer.

In one embodiment, the charge confinement feature is further on the charge trapping layer.

In another embodiment, the charge confinement feature comprises a material that contains negative charge.

In another embodiment, the material comprises metal nitride.

In another embodiment, the material comprises aluminum nitride or aluminum oxynitride whose nitrogen content is richer than oxygen.

In another embodiment, the charge confinement feature comprises a charge trapping material that can trap negative charge.

In another embodiment, the charge trapping material comprises silicon nitride or silicon oxynitride whose nitrogen content is richer than oxygen.

In another embodiment, the charge confinement feature is further on the charge trapping layer and is positioned in the blocking layer, the charge confinement feature having sidewalls that are in contact with the blocking layer.

In another embodiment, the charge confinement feature comprises multiple charge confinement features positioned in the blocking layer, the charge confinement features having inner sidewalls that are in contact with the blocking layer and having sidewalls that are not in contact with the blocking layer.

In another embodiment, the memory device further comprises insulative sidewall spacers at the sidewalls of the control gates of the first and second memory cells, wherein the charge confinement feature comprises at least one charge confinement feature further on the charge trapping layer and positioned in the blocking layer below the sidewall spacers.

In another embodiment, the charge confinement feature comprises sidewall spacers at the sidewalls of the control gates of the first and second memory cells and on the blocking layer.

In another embodiment, the charge confinement feature is further on the charge trapping layer and comprises a charge confinement layer pattern positioned adjacent the first and second sidewalls of the control gates of the first and second memory cells and on the blocking layer.

In another embodiment, the charge confinement feature comprises a film that covers the blocking layer and the facing opposed sidewalls of the first and second memory cells.

In another embodiment, the memory device further comprises insulative sidewall spacers at the sidewalls of the control gates of the first and second memory cells, wherein the charge confinement features are further on the charge trapping layer and positioned on the blocking layer at a horizontal position that is adjacent a horizontal position of the sidewall spacers.

In another aspect, a semiconductor device comprises: a stack comprising a first conductive layer, a second conductive layer on the first conductive layer and a insulation layer between the first and the second conductive layers on an active body of semiconductor material; a memory cell structure including a vertical active region and a plurality of memory cells having memory storage units; wherein the vertical active region is positioned vertically relative to the first and second conductive layers and electrically connected to the active body of semiconductor material; and conductive lines connecting the memory cell structures to peripheral circuitry, wherein a layer comprised of a charge confinement material is further disposed between the first and the second conductive layers.

In one embodiment, a layer comprised of the charge confinement material further covers the lateral surface that contacts the vertical active channel.

In another embodiment, the active body of semiconductor is on a stack comprising transistors that electrically connect and control the memory cell structure.

In another aspect, a method of forming a transistor comprises: providing a body of semiconductor material; providing a tunnel oxide layer on the body; providing a charge trapping layer on the tunnel oxide layer; providing a blocking layer on the charge trapping layer; providing a control gate on the blocking layer, the control gate having first and second sidewalls that define a channel region in the body below the control gate, the first and second sidewalls being spaced apart from each other by a first distance; and forming charge confinement features on the body, the charge confinement features being spaced apart from each other by a second distance that is greater than or equal to the first distance, the charge confinement features limiting migration of charge present in the charge trapping layer.

In one embodiment, forming charge confinement features comprises performing a nitridation process on the blocking layer so that nitride content of a portion of the blocking layer is greater than oxygen content and the portion becomes negatively charged.

In another embodiment, the nitridation process comprises exposing portions of the blocking layer to ammonia or primary amine.

In another embodiment, the method further comprises performing a re-oxidation process on sub-portions of the portions of the blocking layer subjected to the nitridation process so that the sub-portions become insulative and nitridated portion is embedded into the blocking layer.

In another embodiment, the method further comprises forming insulative sidewall spacers at the first and second sidewalls of the control gate and on the blocking layer, wherein forming charge confinement features comprises performing a nitridation process on the insulative sidewall spacers so that nitride content of a portion of the blocking layer is greater than oxygen content and the portion becomes negatively charged.

In another embodiment, the method further comprises forming an insulative layer at the first and second sidewalls of the control gate and on the blocking layer, wherein forming charge confinement features comprises performing a nitridation process on the insulative layer so that nitride content of a portion of the blocking layer is greater than oxygen content and the portion becomes negatively charged.

### BRIEF DESCRIPTION OF THE DRAWINGS

The foregoing and other objects, features and advantages of the embodiments of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings:

FIG. 1 is a cross-sectional diagram of a memory cell in accordance with an embodiment of the present invention.

FIGS. 2-7 are cross-sectional diagrams of a memory cell in accordance with other embodiments of the present invention.

FIGS. 8 and 9 are cross-sectional diagrams of devices comprising two neighboring memory cells in accordance with other embodiments of the present invention.

FIGS. 10A-10D are cross-sectional diagrams of a method of forming the memory cell illustrated in FIG. 1, in accordance with an embodiment of the present invention.

FIGS. 11A-11B are cross-sectional diagrams of a method of forming the memory cell illustrated in FIG. 2, in accordance with other embodiments of the present invention.

FIGS. 12A-12B are cross-sectional diagrams of a method of forming the memory cell illustrated in FIG. 3, in accordance with other embodiments of the present invention.

FIG. 13 is a cross-sectional diagram of a variation of the process of FIGS. 12A-12C, in accordance with other embodiments of the present invention.

FIGS. 14A-14C are cross-sectional diagrams of a method of forming the memory cell illustrated in FIG. 4, in accordance with other embodiments of the present invention.

FIGS. 15A-15B are cross-sectional diagrams of a method of forming the memory cell illustrated in FIG. 5, in accordance with other embodiments of the present invention.

FIGS. 16A and 16B are cross-sectional diagrams of a method of forming the memory cells illustrated in FIG. 6 and FIG. 7, in accordance with other embodiments of the present invention.

FIGS. 17A-17K are perspective views of a method of forming a vertical-channel memory device, in accordance with other embodiments of the present invention.

FIG. 18 is a close-up view of a memory cell in the vertical channel of the memory device formed according to FIGS. 17A-17K.

FIGS. 19A-19F are perspective views of a method of forming a vertical-channel memory device, in accordance with another embodiment of the present invention.

FIG. 20 is a close-up view of memory cells in the vertical channel of the memory device formed according to FIGS. 19A-19F.

FIGS. 21 and 22 are charts illustrating experimental data collected on a sample embodiment.

FIGS. 23 and 24 are charts further illustrating experimental data collected on a sample embodiment.

FIG. 25 is a circuit diagram of a non-volatile memory device including a memory cell array that includes memory cells configured according to the embodiments described herein.

FIG. 26 is a top plan view of a memory cell array, in accordance with embodiments of the present invention.

FIG. 27 is a cross-sectional diagram of a cell string of the memory cell array of FIG. 26, taken along section line I-I′ in accordance with an embodiment of the present invention.

FIG. 28 is a cross-sectional diagram of a stacked memory cell array in accordance with embodiments of the present invention.

FIG. 29 is a block diagram of a memory device in accordance with embodiments of the present invention.

FIG. 30 is a block diagram of the memory cell array, of the memory device of FIG. 29, in accordance with embodiments of the present invention.

FIG. 31 is a block diagram of a memory card that includes a semiconductor device in accordance with the embodiments of the present invention.

FIG. 32 is a block diagram of a memory system that employs a memory module, for example, of the type described herein, in accordance with the embodiments of the present invention.

### DETAILED DESCRIPTION OF EMBODIMENTS

Embodiments of the present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

It will be understood that, although the terms first, second, etc. are used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). When an element is referred to herein as being “over” another element, it can be over or under the other element, and either directly coupled to the other element, or intervening elements may be present, or the elements may be spaced apart by a void or gap. As mentioned above, the drawings are not necessarily to scale, and while certain features in the drawings appear to have rectangular edges that meet at right angles, those features in fact can be oval, contoured, or rounded in shape in the actual devices.

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

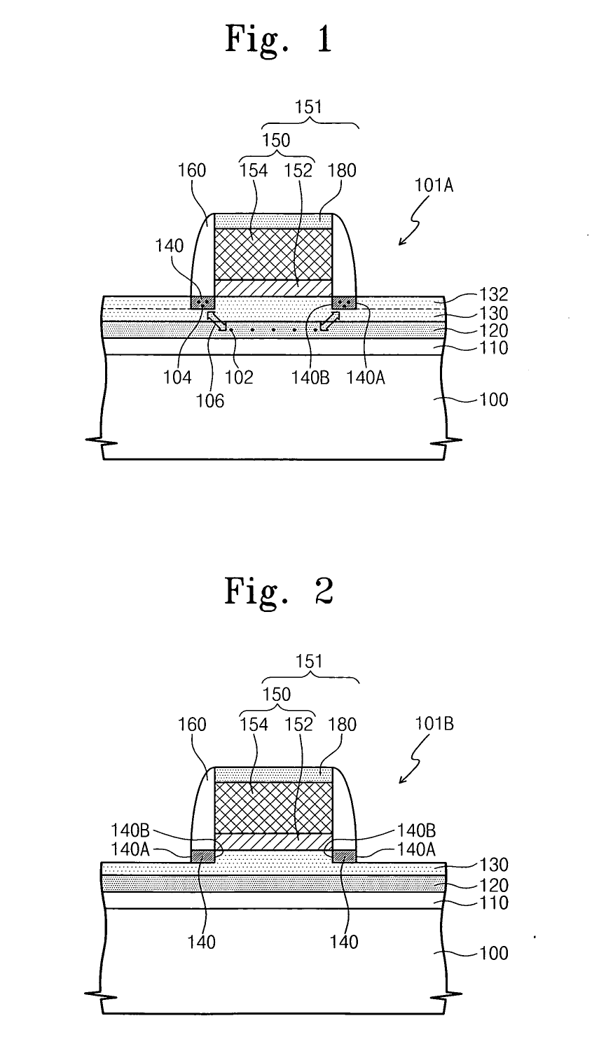

FIG. 1 is a cross-sectional diagram of a memory cell 101A in accordance with an embodiment of the present invention. In the memory cell 101A of FIG. 1, a tunnel oxide layer 110 is provided on a semiconductor substrate 100. A charge trapping layer 120 is provided on the tunnel oxide layer, and a blocking layer 130 is provided on the charge trapping layer 120. A gate structure 151 comprising a first conductive layer 152, a second conductive layer 154, and a mask layer 180 are formed and patterned on the blocking layer 130. In the present embodiment, insulating sidewall spacers 160 are provided on sidewalls of the gate structure 151.

The memory cell 101A is of a type that can be employed in a charge-trap-flash (CTF) device, having a MANOS gate structure. In a MANOS structure, the first and second conductive layers 152, 154 of the gate structure 151 comprise metal layers, the blocking layer 130 comprises aluminum oxide, the charge trapping layer 120 comprises silicon nitride, the tunnel oxide layer 110 comprises silicon oxide and the semiconductor substrate 100 comprises silicon. In other structures, any of a number of suitable materials can be employed for the various layers of the device.

For example, the conductive layers 152, 154 of the gate 151 can comprise a conductive material such as doped polysilicon; titanium or tantalum containing conductive material such as TiN, TaN, TaTi, TaSiN, and combinations thereof tungsten containing conductive material such as W, WN, WSi, and combinations thereof; aluminum containing conductive material, Pd, Ir, Pt, Co, Cr, CoSi, NiSi, and other suitable materials. In some embodiments, the gate 151 can comprise a single conductive layer, while in other embodiments, the gate 151 can comprise two or more conductive layers, for example, the first conductive layer 152 can comprise WN, while the second conductive layer 154 can comprise W.

In various embodiments, the blocking layer 130 can comprise Al₂O₃, ONO, metal oxide such as LaHfO, DyScO and combinations thereof, and a stack of any of these stacked with SiO₂, and other suitable blocking layer materials.

In various embodiments, the charge trapping layer 120 can comprise SiN, a high-k metal oxide such as HfO₂, ZrO₂, TaO₂, HfSiO₂, LaHfO, LaAlO, a high-k metal nitride such as HfON, ZrON, HfSiON, HfAlON, and other materials suitable for operation as a charge trapping layer.

In various embodiments, the tunnel oxide layer 110 can comprise SiN, SiO, combinations thereof, and other materials suitable for operation as a tunnel insulating layer.

In contemporary non-volatile memory cells, the charge trapping layer 120 continuously extends in a direction parallel to the semiconductor substrate. With repetitive programming of a cell, or with the passage of time, electrons confined in the charge trapping region associated with a certain cell can spread in a lateral direction between adjacent cells. This phenomenon of charge spreading can potentially compromise the integrity of the information retained in the subject cell, and in adjacent cells.

Physical cutting or patterning of the charge trapping layer 120 to prevent such migration has met with limited success. In particular, such cutting can damage the processed region, including the channel region of the cell. Also, the additional steps necessary for patterning include a curing process which can further deteriorate retention properties of the resulting device.

A memory cell 101A in accordance with embodiments of the present invention further includes charge confinement features 140. In the embodiment of FIG. 1, the charge confinement features 140 are positioned in the blocking layer 130, underneath the insulative sidewall spacers 160 at the sidewalls of the gate 151. The charge confinement features 140 operate to limit migration of any charge that can later be present in the charge trapping layer 120 during operation of the memory device containing the memory cell 101A.

In the present example, the charge confinement features 140 are positioned at each side of the channel region of the memory cell 101A. For purposes of the present description, the term “channel region” is defined as a region of the semiconductor substrate 100 that lies under the gate 151 that conducts current as a result of the application of a voltage potential to the gate 151, or as a result of charge that is stored in the charge trapping layer 120 that lies between the gate 151 and the semiconductor substrate 100. The above definition applies to both traditional, horizontally configured cells, and to vertical-channel cells; however, for vertical channel cells, the “channel region” lies in the semiconductor vertical channel at a side of, and not necessarily below, the gate.

In one embodiment, the charge confinement features 140 can be formed of a material that has an intrinsic negative charge, or fixed negative charge. In another embodiment, the charge confinement features 140 can be formed of a material that is capable of trapping a negative charge during operation of the device. In this manner, the charge confinement features 140 operate to repel any negative charge present in the charge trapping layer 120, for example, in conventional, horizontal configuration, in a region of the charge trapping layer 120 above the channel region of the semiconductor substrate 100 that lies below the gate 151. In the present application, a charge confinement material is defined as a material that can repel any negative charge present in the charge trapping layer such as for example SiN, AlN, SiOₓN_{y} and AlOₓN_{y} where the content of nitrogen is greater than that of oxygen.

As shown in FIG. 1, the negative charge 104 present in the charge confinement features 140 operates as a potential barrier that retains electrons 102 present in the charge trapping layer 120 by operation of a repulsive force 106, or interaction, between the negative charge 104 and the electrons 102. The charge confinement features 140 operate to limit migration of the electrons 102 in a lateral direction of the charge trapping layer 120 between neighboring memory cells 101. As a result, retention of information is improved along with device reliability, even with increased device integration.

In various embodiments, the charge confinement features 140 can comprise a metal nitride such as AlN. In other embodiments, the charge confinement features 140 can comprise AlOₓN_{y} where the content of nitrogen is greater than that of oxygen, or in other words, where the stoichiometry of the AlOₓN_{y} material is somewhat closer to AlN. In other embodiments, the charge confinement features 140 can comprise HfN. In the above examples an intrinsic, or fixed, negative charge is provided. Depending on the content of nitrogen in the AlOₓN_{y} or SiOₓN_{y} material, silicon oxynitride or metal oxynitride can operate as a charge confinement feature. The greater the content of nitrogen, the more the charge confinement feature can prevent charge from spreading. In one embodiment, the content of nitrogen is more than 0.7 atomic % based on the total number of nitrogen and oxygen atoms.

In other embodiments, the charge confinement features 140 can comprise a material that is suitable for trapping a negative charge during operation of the device, such as SiN. In this example, the negative charge can become trapped in the charge confinement features during a programming operation of the device.

FIGS. 2-7 are cross-sectional diagrams of a memory cell in accordance with other embodiments of the present invention.

Referring to the embodiment of FIG. 2, it can be seen that this embodiment has a configuration that is similar to that of the embodiment of FIG. 1. In particular, in both embodiments of FIGS. 1 and 2, the charge confinement features 140 lie on the blocking layer 130, and the charge confinement features 140 have inner sidewalls 140B that are entirely in contact with the blocking layer 130, or alternatively, the charge confinement features 140 have inner sidewalls 140B that are in contact with the blocking layer 130 over a majority of their height.

One difference between the embodiments of FIGS. 1 and 2, however, lies in that in the memory cell 101B configuration of FIG. 2, the opposed outer sidewalls 140A of the charge confinement features 140 have portions thereof that are not in contact with the blocking layer 130, or, alternatively, the opposed outer sidewalls 140A of the charge confinement features 140 are not at all in contact with the blocking layer 130. For example, in the memory cell 101A embodiment of FIG. 1, the charge confinement features 140 are embedded in the blocking layer 130 and surrounded by an upper portion of the blocking layer 132. In contrast, in the memory cell 101B embodiment of FIG. 2, the inner sidewalls 140B of the charge confinement features 140 are adjacent the blocking layer 130, while majority portions of the outer sidewalls 140A are not in contact with the blocking layer 130.

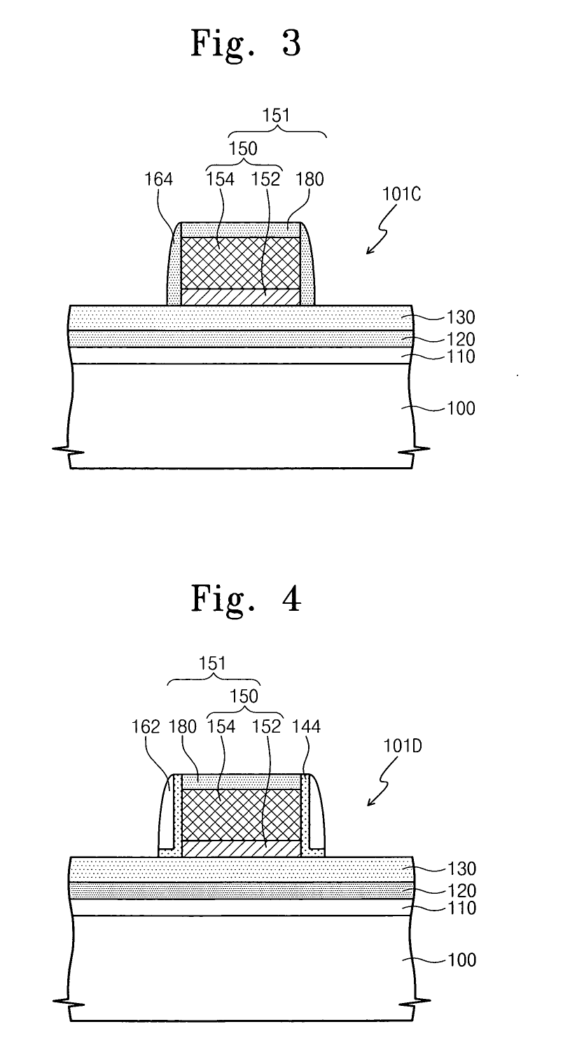

Referring to the embodiment of FIG. 3, it can be seen that in the memory cell 101C of this embodiment, the charge confinement features comprise sidewall spacer charge confinement features 164 positioned at sidewalls of the gate structure 151 and on the blocking layer 130. In other words, the gate structure 151 sidewall spacers themselves are the confinement features 164 that limit migration of charge in a lateral direction of the underlying charge trapping layer 120. The sidewall spacer confinement features 164 of the embodiment of FIG. 3 can comprise a material that has an intrinsic negative charge, or fixed negative charge, or can be formed of a material that is capable of trapping a negative charge during operation of the device, as described above in connection with the description of the above embodiments.

Referring to the embodiment of FIG. 4, it can be seen that in the memory cell 101D of this embodiment, the charge confinement features comprise an L-shaped spacer layer 144 positioned at sidewalls of the gate structure 151 and on the blocking layer 130. Insulative sidewall spacers 162 lie at side portions of the vertical portion of the L-shaped spacer layer 144 and on the horizontal portion of the L-shaped spacer layer 144. In this embodiment, the L-shaped spacer layer 144 itself operates as the charge confinement features that limit migration of charge in a lateral direction of the underlying charge trapping layer 120. The L-shaped spacer layer 144 of the embodiment of FIG. 4 can comprise a material that has an intrinsic negative charge, or fixed negative charge, or can be formed of a material that is capable of trapping a negative charge during operation of the device, as described above in connection with the description of the above embodiments.

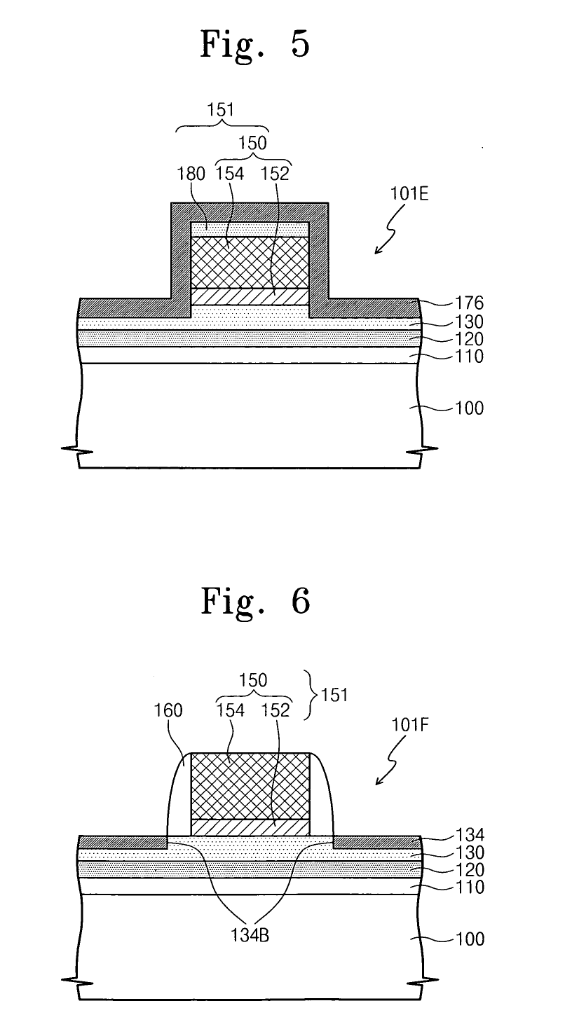

Referring to the embodiment of FIG. 5, it can be seen that in the memory cell 101E of this embodiment, the charge confinement features are provided by a confinement feature film layer 176 applied to the top of the blocking layer 130, sidewalls of the gate structure 151 and a top of the gate structure 151, for example, on the hard mask 180 positioned at a top of the gate structure In this embodiment, the charge confinement feature film layer 176 operates as the confinement features that limit migration of charge in a lateral direction of the underlying charge trapping layer 120. The confinement feature film layer 176 of the embodiment of FIG. 5 can comprise a material that has an intrinsic negative charge, or fixed negative charge, or can be formed of a material that is capable of trapping a negative charge during operation of the device, as described above in connection with the description of the above embodiments.

Referring to the embodiment of FIG. 6, it can be seen that the memory cell 101F of this embodiment has a configuration that is similar to that of the embodiment of FIG. 2. In particular, in both embodiments of FIGS. 6 and 2, the charge confinement features 134, 140 lie on the blocking layer 130, and the charge confinement features 134, 140 have inner sidewalls 134B, 140B that are entirely in contact with the blocking layer 130, or alternatively, the charge confinement features 134, 140 have inner sidewalls 134B, 140B that are in contact with the blocking layer 130 over a majority of their height.

One difference between the embodiments of FIGS. 6 and 2, however, lies in that in the memory cell 101B configuration of FIG. 2, the charge confinement features 140 are local to the region of the gate structure 151. For example, the charge confinement features 140 have a width in the horizontal direction of the substrate 100 that is substantially the same as the width of the lower portions of the insulative sidewall spacers 160 that lie above them. In contrast, in the embodiment of FIG. 6, the charge confinement features 134 extend in a horizontal direction from an outer edge of the sidewall spacers 160 and are continuous between the gate structures of neighboring memory cells 101F.

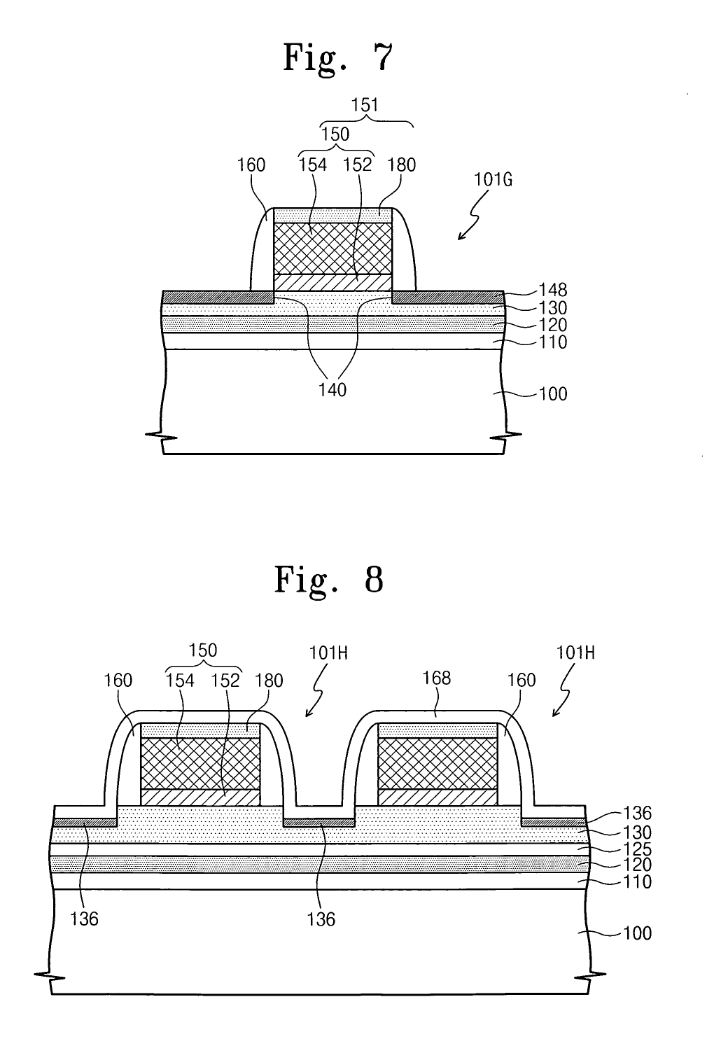

Referring to the embodiment of FIG. 7, it can be seen that the memory cell 101G of this embodiment has a configuration that is similar to that of the embodiment of FIG. 6. In particular, in both embodiments of FIGS. 6 and 7, the charge confinement features 134, 148 extend in a horizontal direction and are continuous between gate structures of neighboring memory cells 101F. In addition, both charge confinement features 134, 148 have inner sidewalls 134B, 148B that are entirely in contact with the blocking layer 130, or alternatively, the charge confinement features 134, 148B have inner sidewalls 134B, 148B that are in contact with the blocking layer 130 over a majority of their height.

One difference between the embodiments of FIGS. 6 and 7, however, lies in that in the memory cell 101G configuration of FIG. 7, the charge confinement features 140 are further positioned at least partially beneath the insulative sidewall spacers 160 of the gate structure 151.

FIG. 8 is a cross-sectional diagram of two neighboring memory cells in accordance with other embodiments of the present invention. In this diagram it can be seen that the memory cells 101H of this embodiment have a configuration that is similar to that of the embodiment of FIG. 6. In particular, in both embodiments of FIGS. 8 and 6, the charge confinement features 136, 134 lie on the blocking layer 130, and the charge confinement features 136, 134 extend in a horizontal direction from an outer edge of the sidewall spacers 160 and are continuous between neighboring gate structures 101F.

One difference between the embodiments of FIGS. 8 and 6, however, lies in that in the configuration of FIG. 8, the charge confinement features 136 are recessed in the blocking layer 130 such that a top portion of the charge confinement features 136 lies below a top surface of the blocking layer 130; whereas in the configuration of FIG. 6, the charge confinement features 134 are substantially co-planar with the top of the blocking layer 130. In the FIG. 8 illustration, it can be seen that an insulative capping layer 168 is applied to the resulting structure. The insulative capping layer 168 can be applied to any of the embodiments disclosed herein.

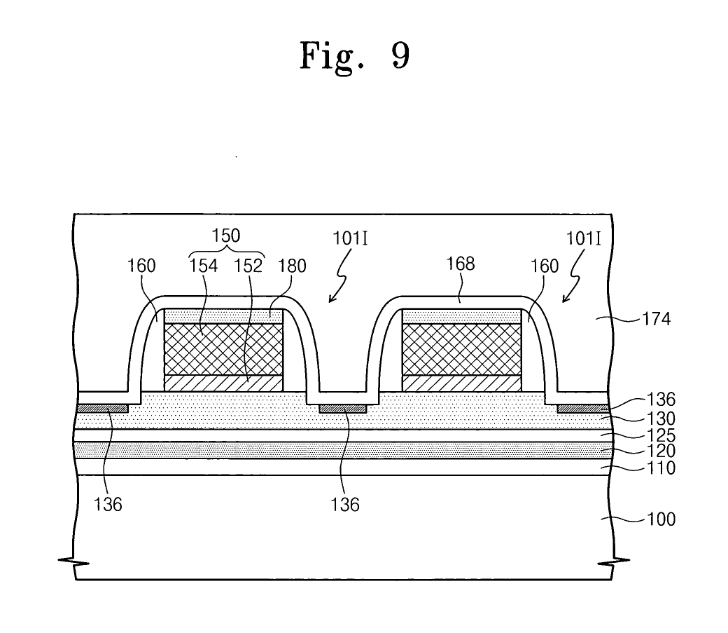

FIG. 9 is a cross-sectional diagram of two neighboring memory cells in accordance with other embodiments of the present invention. In this diagram it can be seen that the memory cells 101I of this embodiment have a configuration that is similar to that of the embodiment of FIG. 8. In particular, in both embodiments of FIGS. 9 and 8, the charge confinement features 172, 136 lie on the blocking layer 130, and the charge confinement features 172, 136 extend in a horizontal direction and are continuous between neighboring gate structures 101I, 101H.

One difference between the embodiments of FIGS. 9 and 8, however, lies in that in the configuration of FIG. 9, the charge confinement features 172 further lie below the insulative sidewall spacers 160.

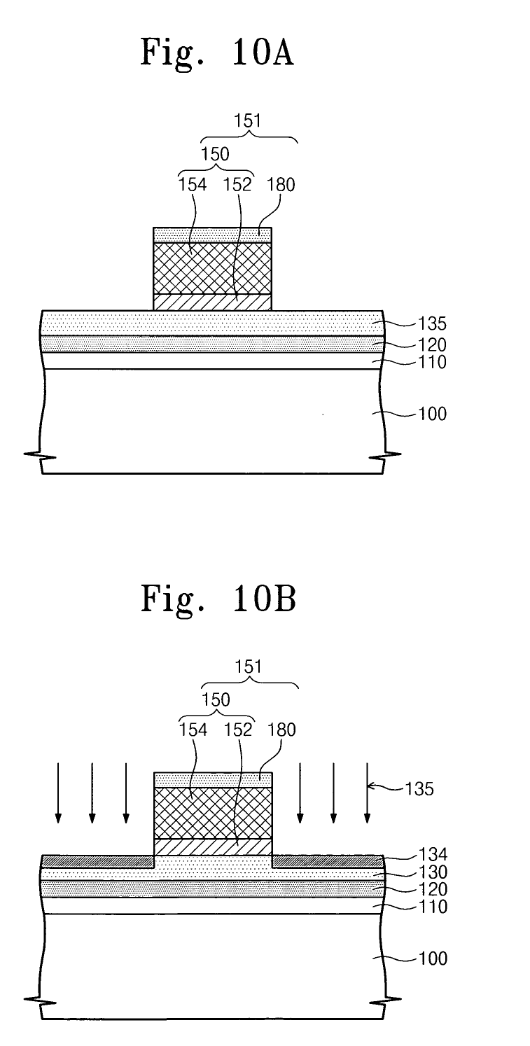

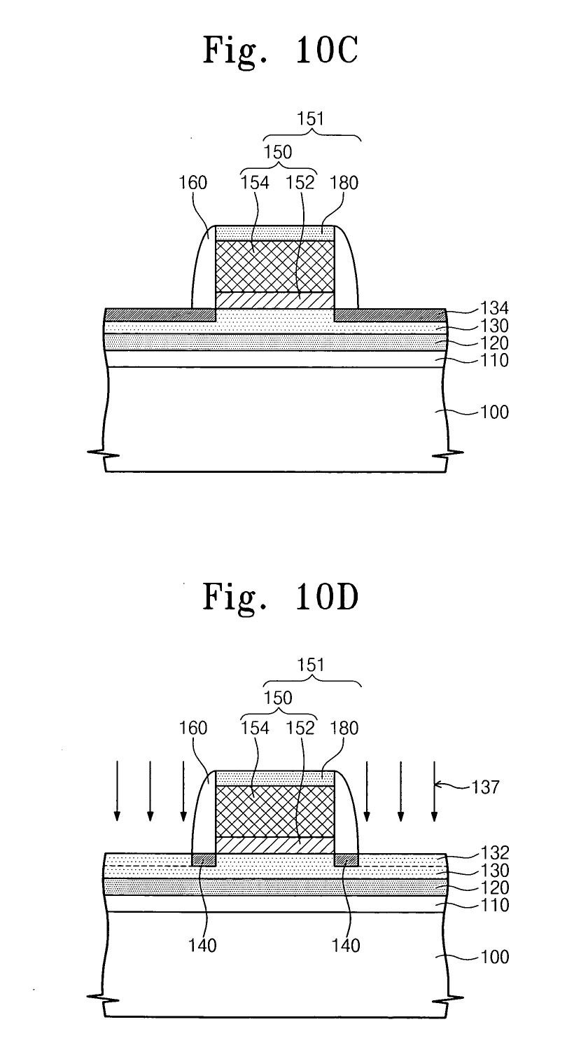

FIGS. 10A-10D are cross-sectional diagrams a method of forming the memory cell illustrated in FIG. 1, in accordance with an embodiment of the present invention. Referring to FIG. 10A, a tunneling oxide layer 110, a charge trapping layer 120 and a blocking layer 130 are sequentially formed on a semiconductor substrate 100. A first conductive layer 152, a second conductive layer, and a mask layer 180 are formed and patterned on the resulting structure, to form a gate structure 151 on the blocking layer 130. The various layers can be formed for example, of suitable materials, as described above.

Referring to FIG. 10B, in one embodiment, the blocking layer 130 can be formed of a metal nitride material such as AlOₓN_{y}. A nitrogen enriching process 135 is employed to transform an upper portion of the blocking layer 130 so that it has an enriched nitrogen content, for example, so that the content of nitrogen is greater than that of oxygen, or, in other words, so that the stoichiometry of the resulting material is somewhat closer to AlN. In this manner, the resulting material of the resulting enriched blocking layer 134 has the properties of a material having a fixed, negative, charge. During this process, the gate structure 151 operates as a mask so that regions of the blocking layer 130 that lie below the gate structure 151 are not thus enriched.

Referring to FIG. 10C, insulative spacer structures 160 are formed on sidewalls of the gate structure and on the enriched blocking layer 134 according to conventional sidewall spacer formation techniques.

Referring to FIG. 10D, regions of the enriched blocking layer 134 that lie beyond the insulative sidewall spacers 160 are subjected to an oxidation process 137 that reverts the stoichiometry of the material so that it becomes oxygen-rich AlOₓN_{y}. In this manner, the resulting re-converted upper portions 132 of the blocking layer 130 are substantially no longer negatively charged, but instead are once again made to be insulative. The insulative sidewall spacers 160 operate as a mask during this procedure so that the resulting charge confinement features 140 lying below the sidewall spacers remain substantially negatively charged. This process results in the formation of the memory cell 101A configuration shown in FIG. 1.

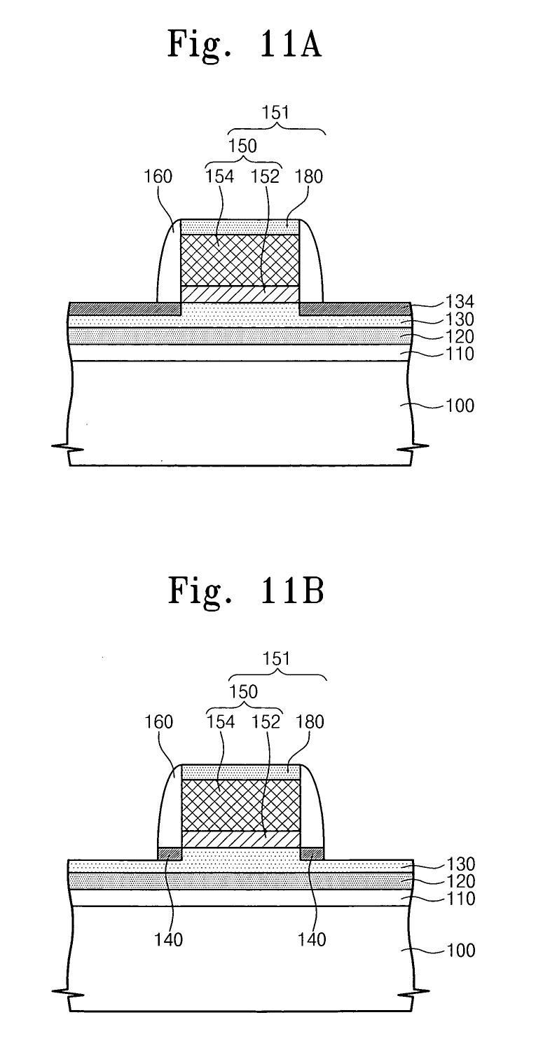

FIGS. 11A-11B are cross-sectional diagrams a method of forming the memory cell illustrated in FIG. 2, in accordance with other embodiments of the present invention. In this embodiment, the process steps shown and described above in connection with FIGS. 10A-10C are performed, resulting in the structure shown in FIG. 11A.

Referring to FIG. 11B, portions of the blocking layer 134 lying between neighboring gate structures are removed, using the insulative sidewall spacers 160 and the mask layer 180 of the gate structure 151 as a mask. This process results in the formation of the memory cell 101B configuration shown in FIG. 2.

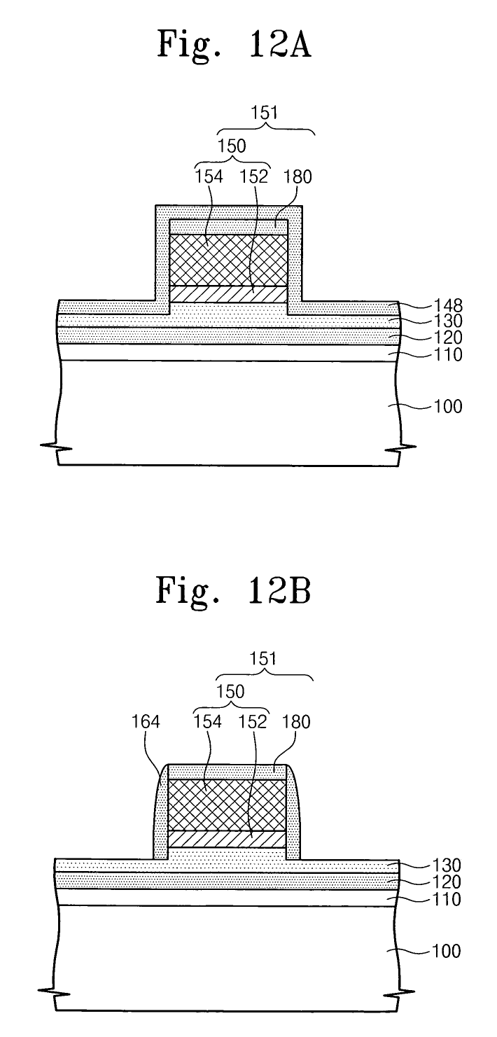

FIGS. 12A-12B are cross-sectional diagrams of a method of forming the memory cell illustrated in FIG. 3, in accordance with other embodiments of the present invention. In this embodiment, the process steps shown and described above in connection with FIG. 10A are performed, resulting in the structure shown in FIG. 12A.

Referring to FIG. 12A, a layer 148 of metal nitride material, for example, AlN, is applied to the resulting structure, covering the blocking layer 130 and the top and sidewalls of the gate structure 151.

Referring to FIG. 12B, an anisotropic etch process is performed on the layer 148, resulting in the formation of sidewall spacers 164 that are negatively charged and therefore serve as charge confinement features for the resulting memory cell 101C. This process results in the formation of the memory cell 101C configuration shown in FIG. 3.

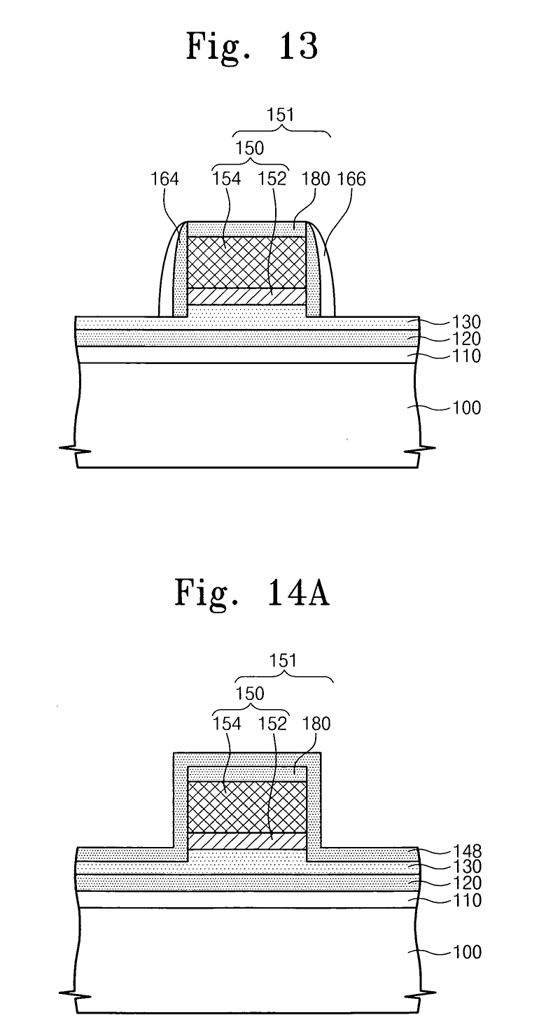

FIG. 13 is a cross-sectional diagram of a variation of the process of FIGS. 12A-12C, in accordance with other embodiments of the present invention. In this embodiment, after forming the charge confinement features in the form of sidewall spacers 164, an insulative second sidewall spacer 166 can be formed. In this embodiment, a layer of SiN is applied to the structure resulting from the FIG. 12B process. The SiN layer is anisotropically etched to form an insulative SiN second sidewall spacer 166.

In an alternative embodiment, the positions of the second insulative sidewall spacer 166 and the charge confinement features of the first sidewall spacers 164 can be reversed. That is the first sidewall spacers 164 can comprise an insulative material and the second sidewall spacers 166 can comprise a material that is suitable for charge confinement.

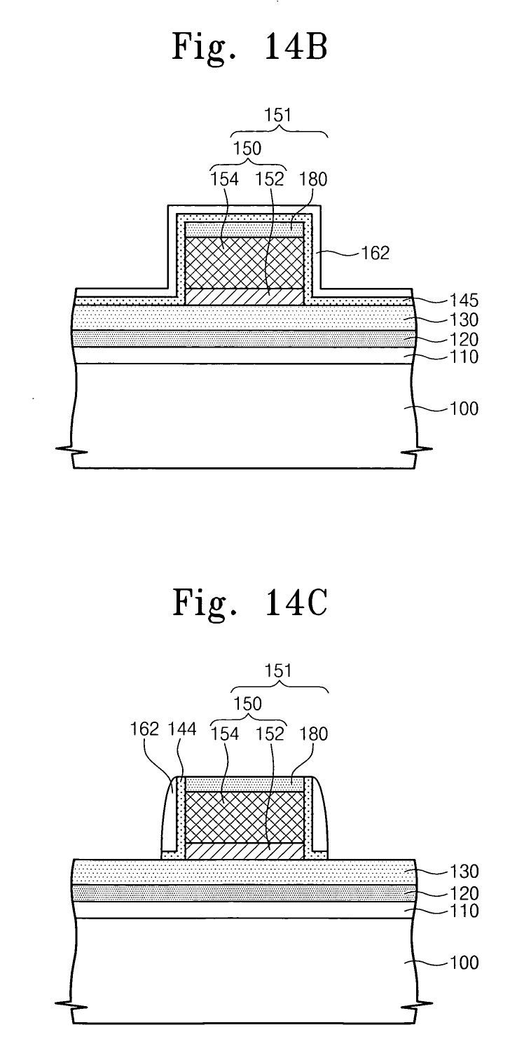

FIGS. 14A-14C are cross-sectional diagrams of a method of forming the memory cell illustrated in FIG. 4, in accordance with other embodiments of the present invention. In this embodiment, the process steps shown and described above in connection with FIG. 10A are performed, resulting in the structure shown in FIG. 14A.

Referring to FIG. 14A, a first conformal layer 145 of metal nitride material, for example, AlN, is applied to the resulting structure, covering the blocking layer 130 and the top and sidewalls of the gate structure 151.

Referring to FIG. 14B, a second conformal layer 162 of insulative material, for example, SiN or SiO₂, is applied to the resulting structure, covering the first conformal layer 145.

Referring to FIG. 14C, an anisotropic etch process is performed on the first and second conformal layers 145, 148, resulting in the formation of insulative sidewall spacers 162 that lie at side portions of the vertical portion of the L-shaped spacer layer 144 and on the horizontal portion of the L-shaped spacer layer 144. The resulting L-shaped spacer layer 144 portions are negatively charged and therefore serve as charge confinement features for the resulting memory cell 101D. This process results in the formation of the memory cell 101D configuration shown in FIG. 4.

In an alternative embodiment, the positions of the charge confinement features of the L-shaped spacer layer 144 and the sidewall spacer 162 can be reversed. That is, the L-shaped spacer layer 144 can comprise an insulative material and the sidewall spacers 162 can comprise a material that is suitable for charge confinement. In another embodiment, both the L-shaped spacer layer 144 and the sidewall spacers 162 can comprise a material that is suitable for charge confinement.

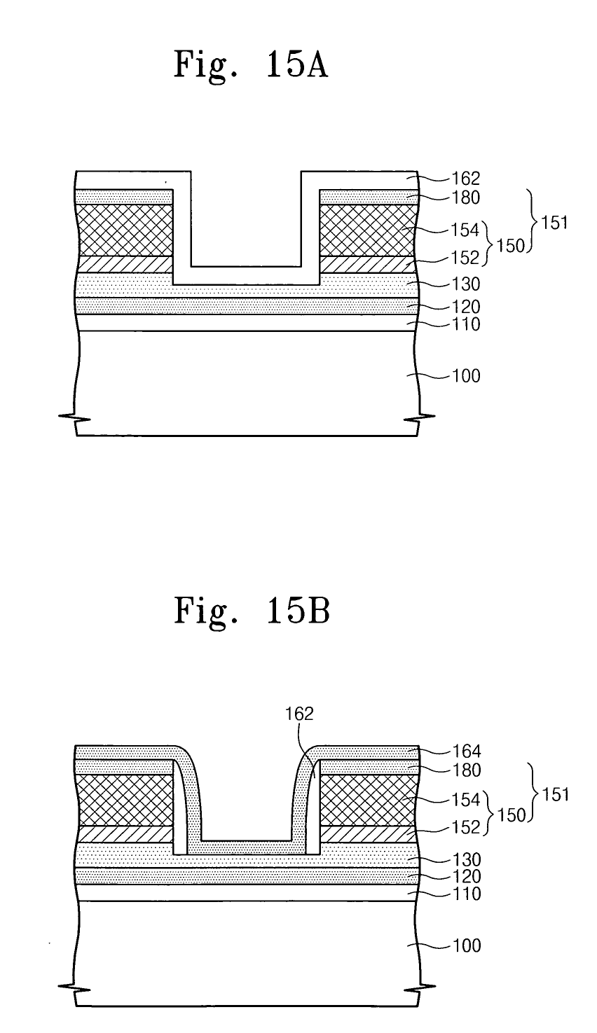

FIGS. 15A-15B are cross-sectional diagrams of a method of forming the memory cell illustrated in FIG. 5, in accordance with other embodiments of the present invention. In this embodiment, the process steps shown and described above in connection with FIG. 10A are performed, resulting in the structure shown in FIG. 15A.

Referring to FIG. 15A, a first conformal layer 162 of metal nitride material, for example, AlN, is applied to the resulting structure, covering the blocking layer 130 and the top and sidewalls of the gate structure 151. This process results in the formation of the memory cell 101E configuration shown in FIG. 5.

Referring to FIG. 15B, in an alternative embodiment, a first conformal layer 162 of insulative material, for example, SiN or SiO₂, is applied to the resulting structure, covering the blocking layer 130 and the top and sidewalls of the gate structure 151. The first conformal layer is anisotropically etched to form insulative spacers 162 at sidewalls of the gate structure. A second conformal layer 164 of metal nitride material, for example, AlN, is applied to the resulting structure. This process results in the formation of a variation of the memory cell 101E configuration shown in FIG. 5.

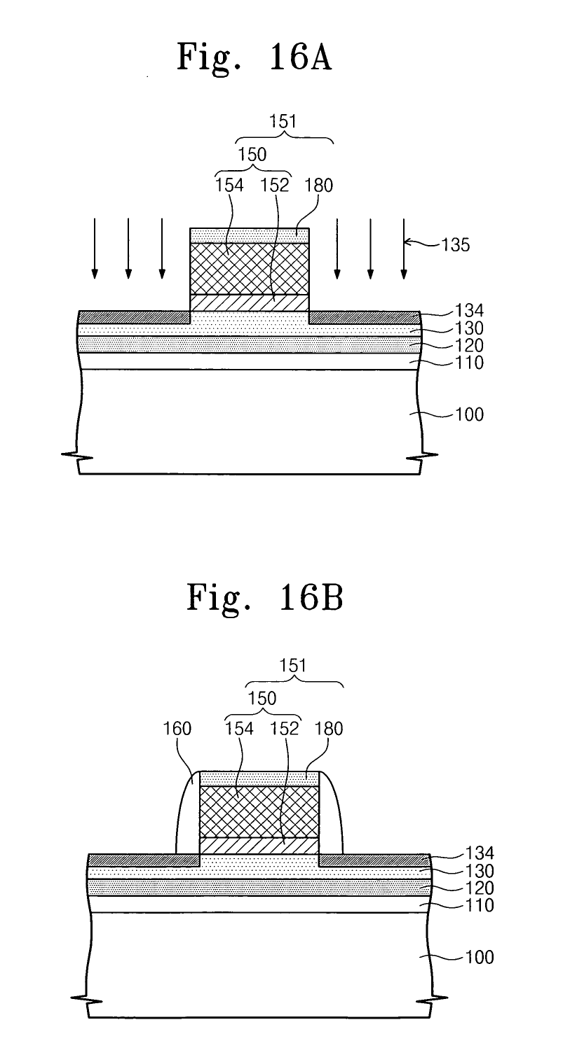

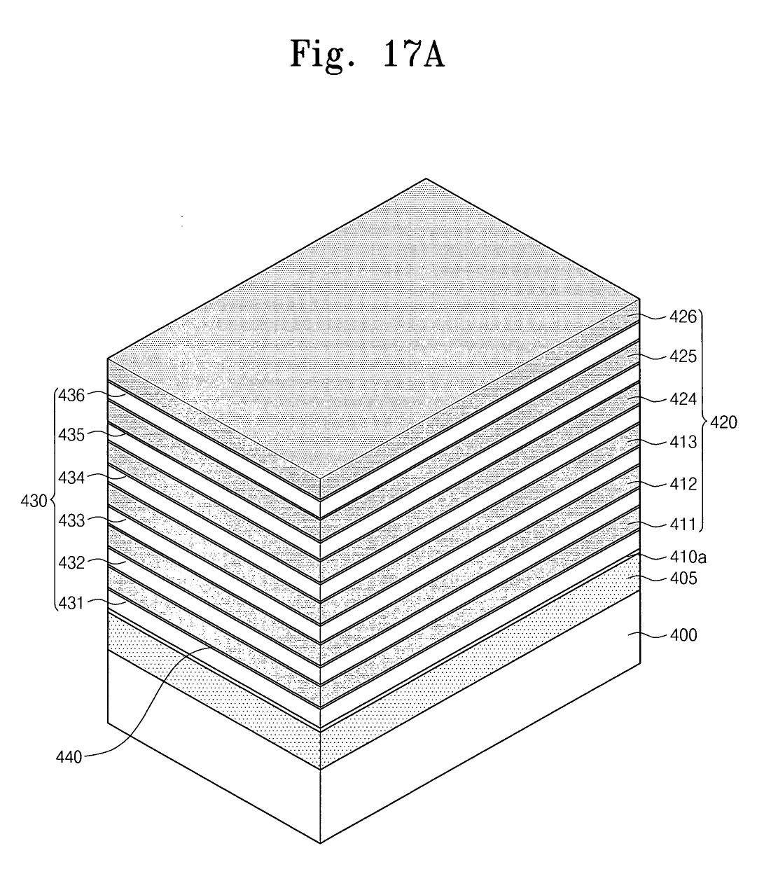

FIGS. 16A and 16B are cross-sectional diagrams of a method of forming the memory cells illustrated in FIG. 6 and FIG. 7, in accordance with other embodiments of the present invention. In this embodiment, the process steps shown and described above in connection with FIGS. 10A-10C are performed, resulting in the structure shown in FIG. 16B. If sidewall spacers 160 are then formed on sidewalls of the gate structure 160, on the resulting metal nitride layer 134, the memory cell 101G configuration are formed as shown in FIG. 7.

In an embodiment where an insulative sidewall spacer 160 is made to be present at sidewalls of the gate structure 151 prior to the nitridation process 135, the process results in the formation of the memory cell 101F configuration shown in FIG. 6.

In forming the memory cells illustrated in FIG. 8, in accordance with other embodiments of the present invention, the process steps shown and described above in connection with FIG. 10A are performed, resulting in the structure shown in FIG. 10A. In this embodiment, the blocking layer 130 may be a single or multiple layers, for example, comprising a high k metal oxide layer and a silicon oxide layer 125. An oxide spacer 160 is then formed by deposition and subsequent etching, as described above. During the etching of the oxide spacers, the blocking layer 130 becomes slightly recessed. A locally nitrided region 136 is then formed between adjacent oxide spacers 160, for example using the above nitridation process. A capping oxide 168 is then formed over the resulting structure to protect the locally nitrided region 136, resulting in the memory cell configuration shown in FIG. 8.

In forming the memory cells illustrated in FIG. 9, in accordance with other embodiments of the present invention, the same process steps shown and described above in connection with FIG. 8 are performed. However, the local nitridation process is not performed until after the capping layer 160 is applied. In this manner, the locally nitrided region 136 is formed by ion implantation of nitrogen through the capping oxide layer 168. This results in the memory cell configuration shown in FIG. 8.

Principles of the present inventive embodiments apply equally well to the emerging vertical-channel memory device configurations currently under development. Examples of such devices are described in U.S. patent application Ser. No. 12/471,975, filed May 26, 2009, entitled “Memory Devices Including Vertical Pillars and Methods of Manufacturing and Operating the Same”, the content of which is incorporated herein by reference, in its entirety.

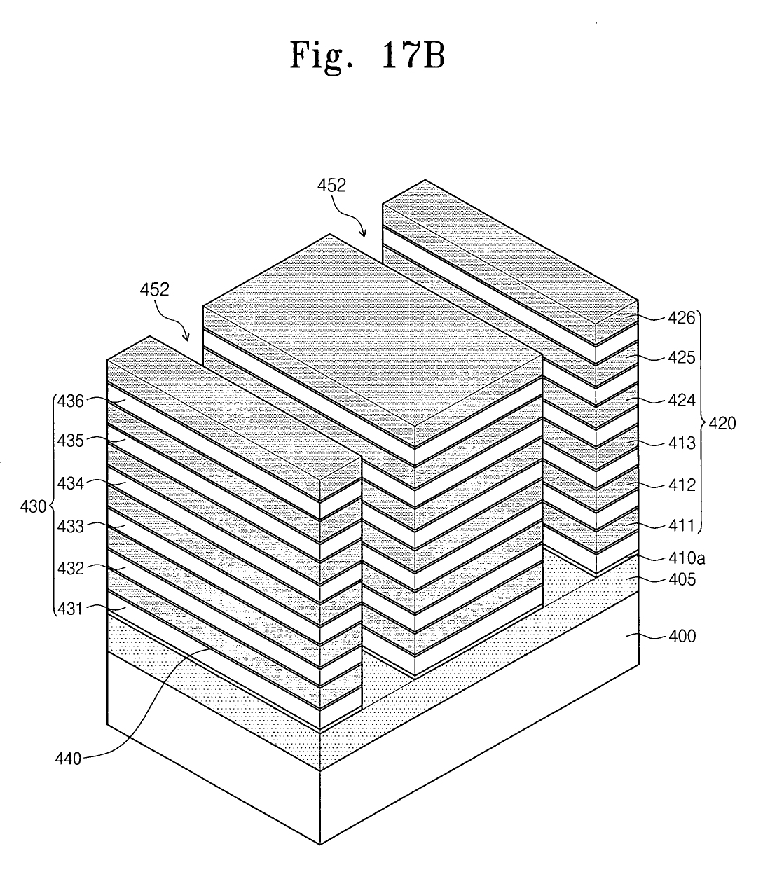

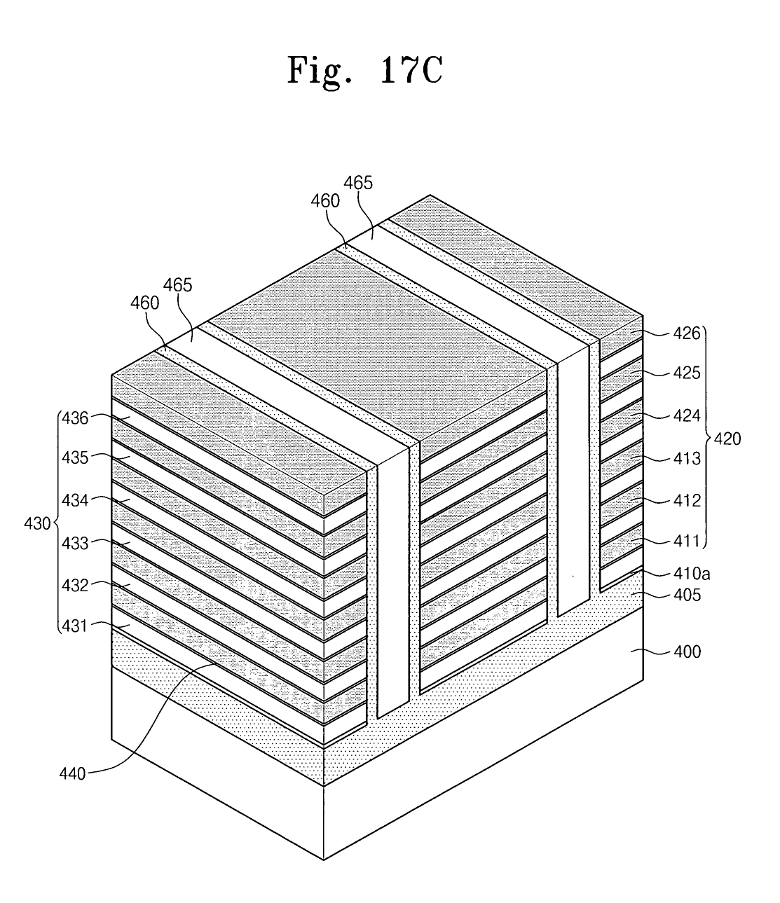

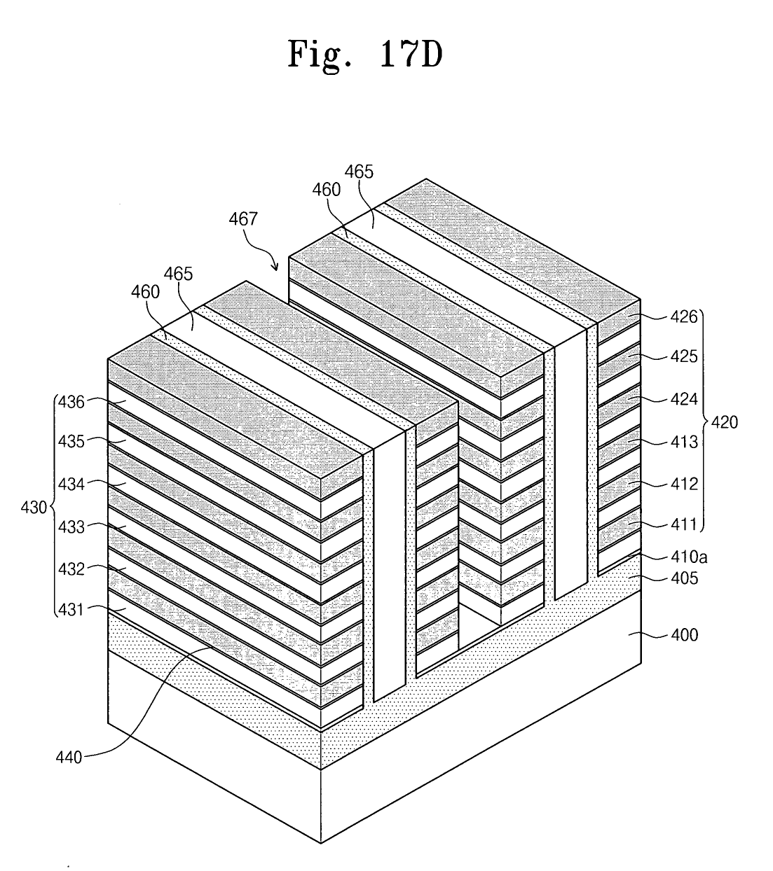

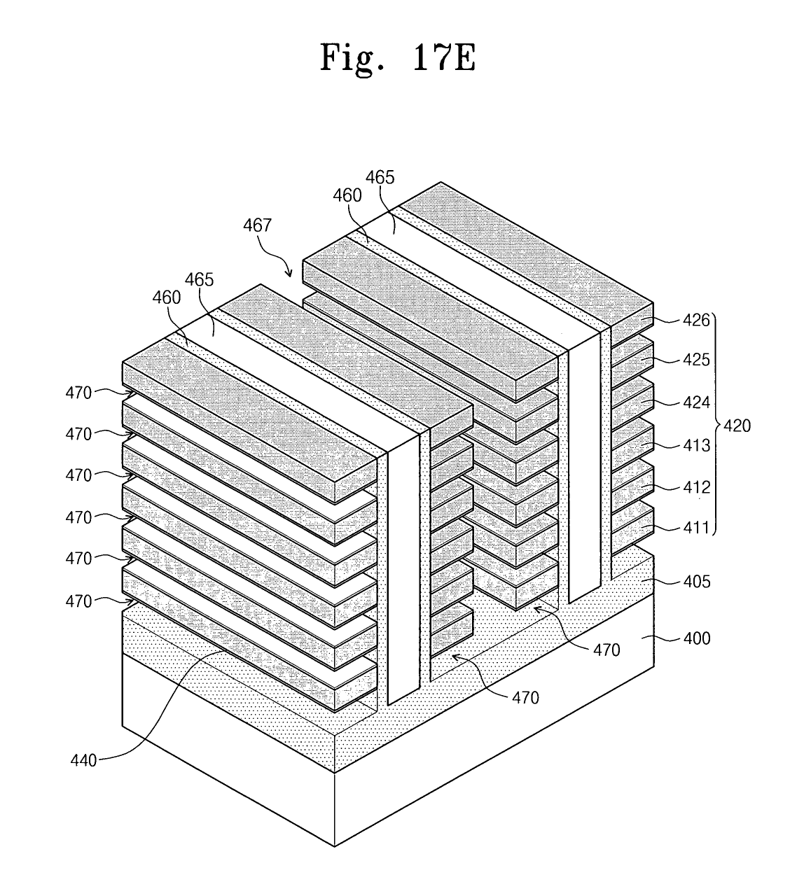

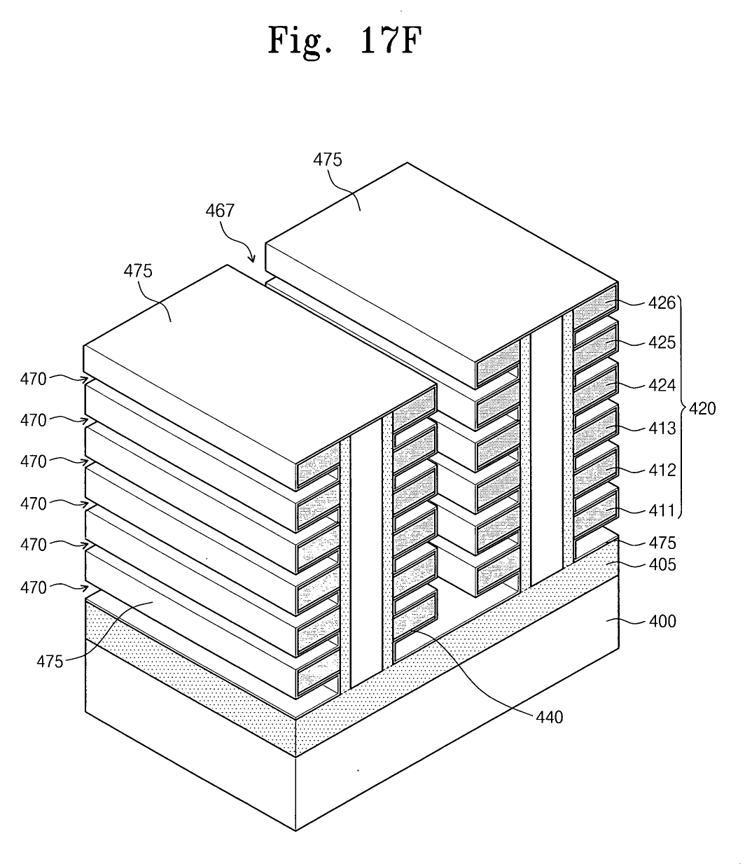

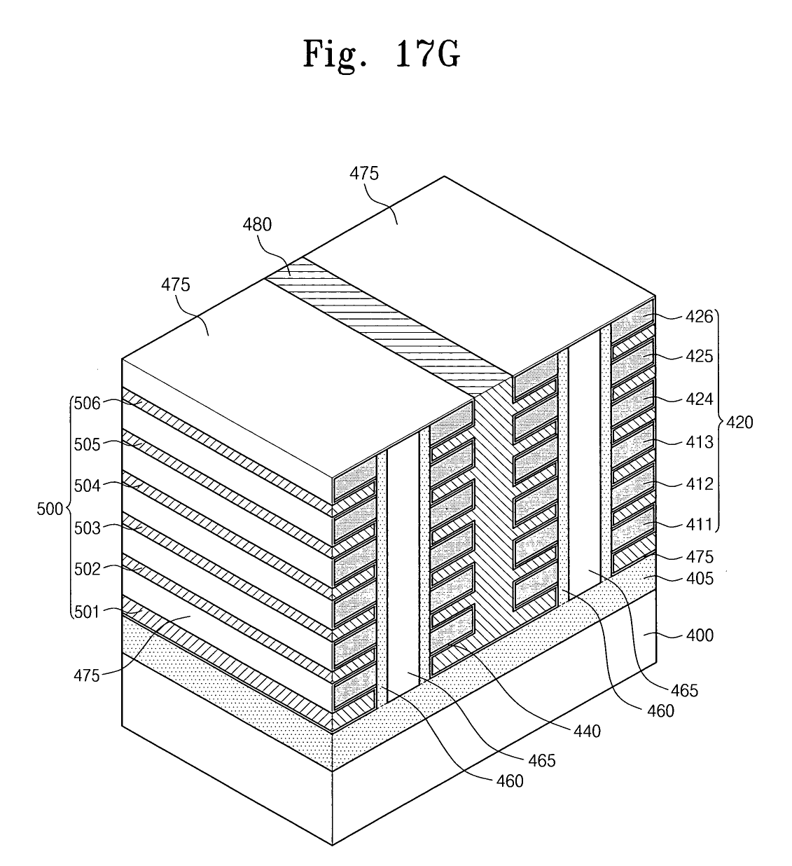

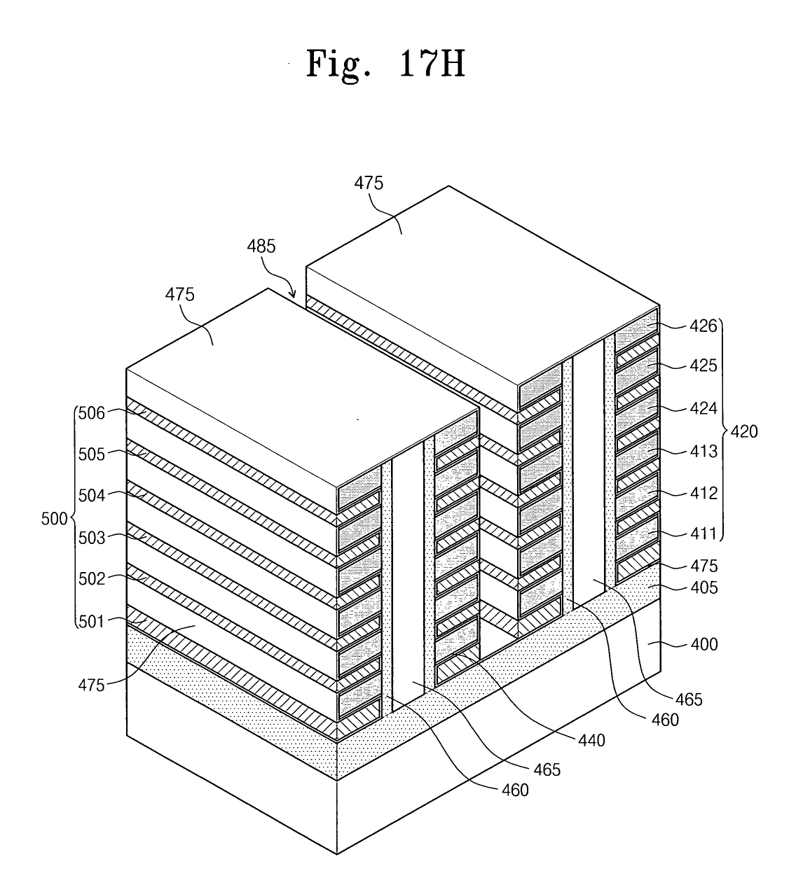

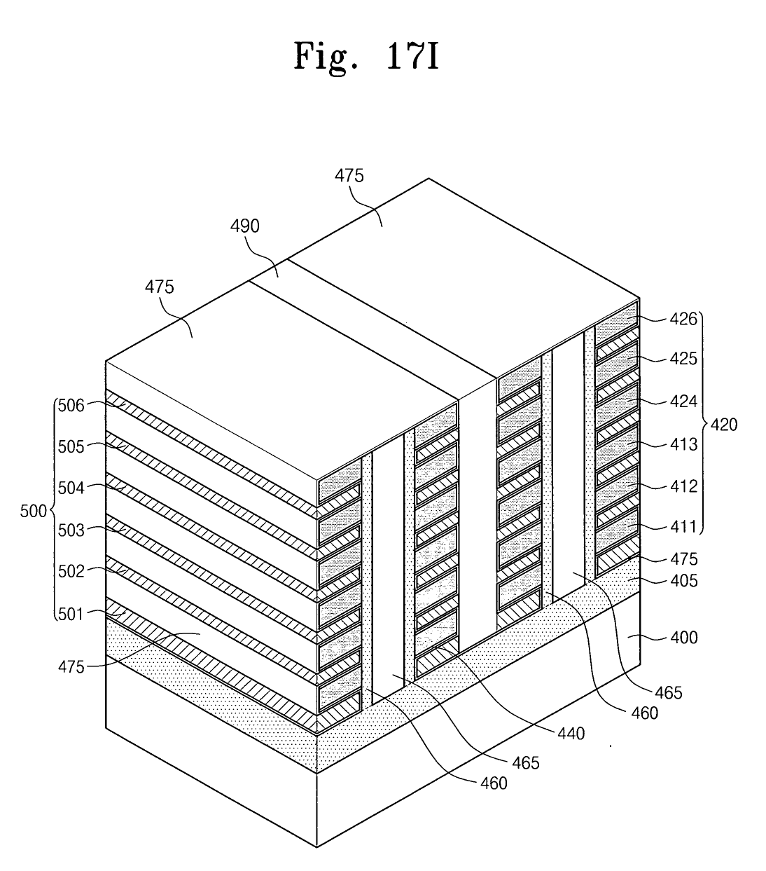

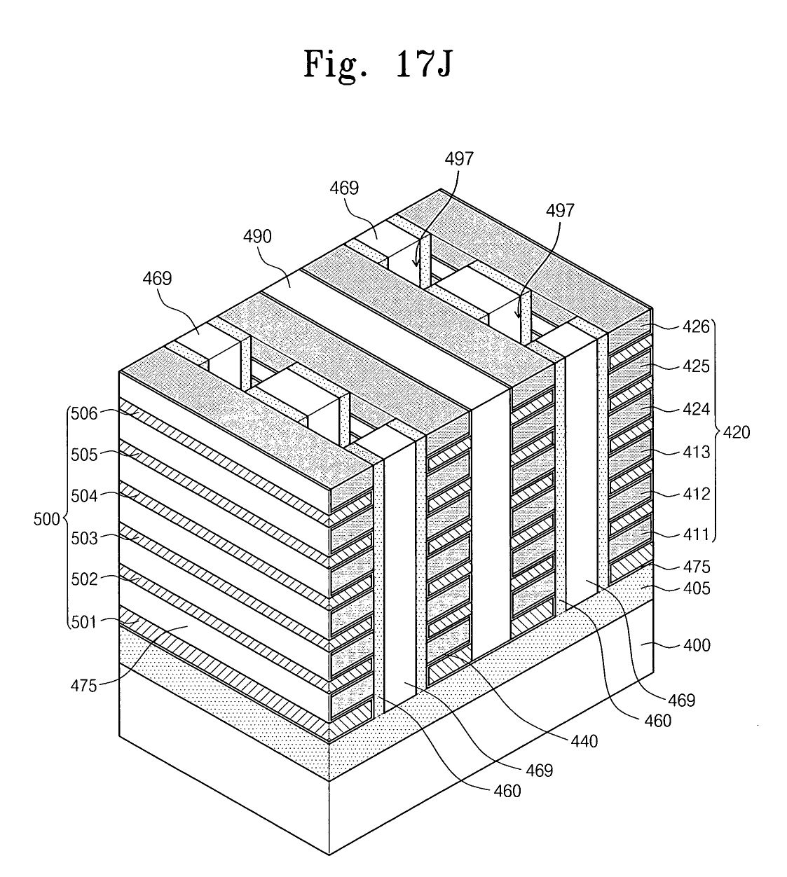

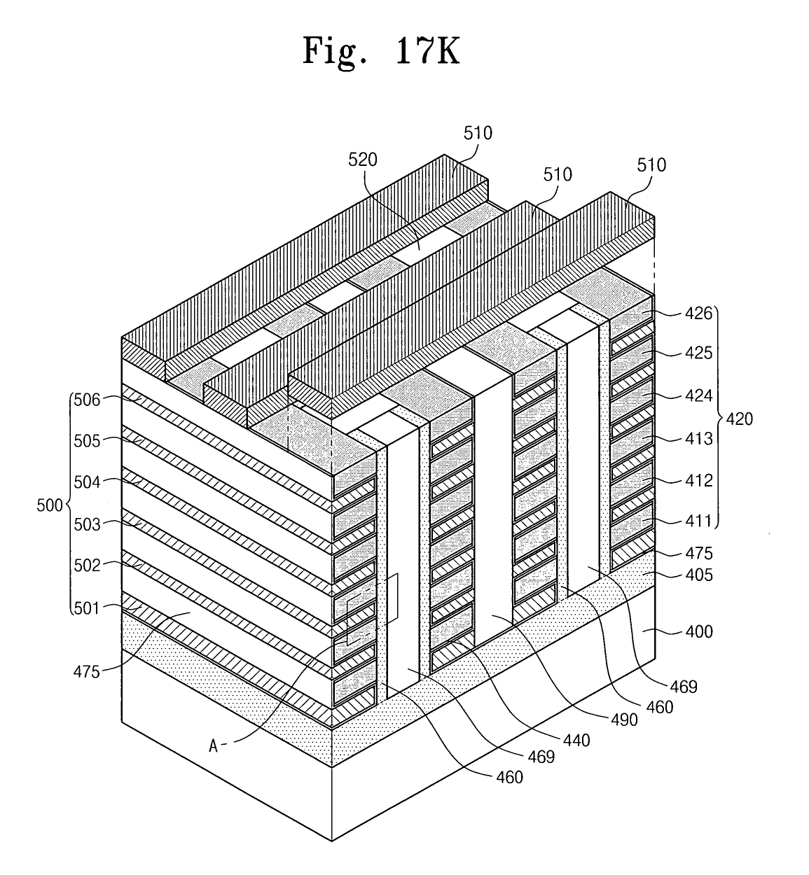

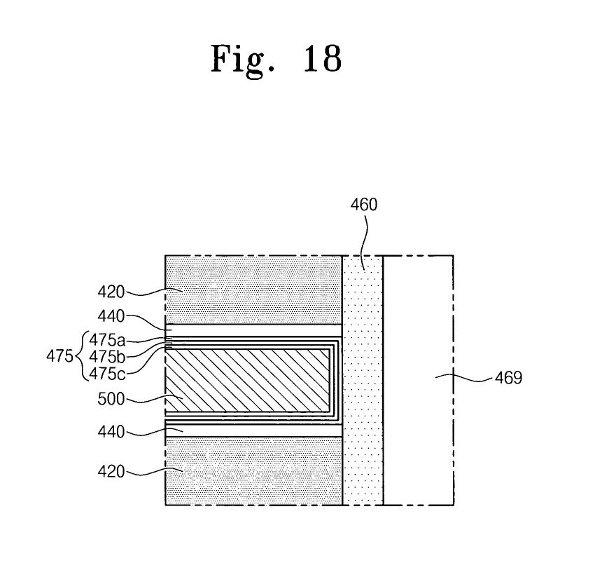

FIGS. 17A-17K are perspective views of a method of forming a vertical-channel memory device, in accordance with other embodiments of the present invention. FIG. 18 is a close-up view of a memory cell in the vertical channel of the memory device formed according to FIGS. 17A-17K.

Referring to FIG. 17K and FIG. 18, one example embodiment of a vertical-channel memory device includes a vertical channel 460 of semiconductor material that is separated from another vertical channel by a dielectric layer 469. A memory cell gate 500, for example, formed of tungsten, is surrounded by a blocking oxide layer 475c, a charge trapping layer 475b and a tunnel oxide layer 475a. Charge confinement features in the form of layers 440 are on opposed faces of the tunnel oxide layer 475a. In one example, the charge confinement features comprise AlN. In other embodiments, the charge confinement features 440 comprise other materials described herein as being suitable for charge confinement. Neighboring memory cell gates are separated from each other in the vertical direction by isolation layers 420.

The charge confinement features 440 operate in the manner described herein to limit the migration of charge stored in the charge trapping layer 475b to the vertical portion of the charge trapping layer 475b between the sidewall of the gate 500 and the vertical channel 460. The presence of the charge confinement features 440 thus prevents the migration of charge present in the charge trapping layer 475b into the horizontal portions of the charge trapping layer 475b. Such migration of charge along the horizontal walls of the gate 500 would otherwise result in loss of information stored in the memory cell.

Referring to FIG. 17A, a method of forming the vertical-channel memory device illustrated in FIG. 17K and FIG. 18 will now be described. A substrate 400, 405 is prepared. In one embodiment, a doped active region 405 is formed on the substrate 400 from a wafer of single-crystal silicon. The doped active region 405 may comprise a single-crystal semiconductor material substrate. If so, it may provide a seed layer for later formation of single-crystal vertical pillars that will form the vertical channels. Alternatively, the doped active region is formed of polysilicon by deposition which may be later further transformed to single-crystalline, for example by laser apparatus. In other embodiments the substrate comprises a polycrystalline semiconductor material. A lower-most interlayer dielectric layer 410 is provided on the substrate 405. In certain embodiments, the lower-most interlayer dielectric layer 410a is sufficiently thin so that an inversion layer can be created in the underlying semiconductor material of the substrate 100 when a suitable voltage is applied to a resulting lowermost gate. Multiple alternating interlayer dielectric layers 420, including in this example, layers 411, 412, 413, 424, 425, and 426 and multiple sacrificial layers 430, including in this case, layers 431, 432, 433, 434, 435, and 436 are formed on the lower-most interlayer dielectric layer 110a. In one embodiment, the interlayer dielectric layers 420 and the sacrificial layers 430 have etch selectivity with respect to each other. For example, the interlayer dielectric layers 420 can comprise silicon oxide and the sacrificial layers 430 can comprise silicon nitride. In one embodiment, the sacrificial layers 430 are formed of a material that can readily be removed by a wet etching process.

Referring to the close-up view of FIG. 18, above the lower-most interlayer dielectric layer 410a, and above and below each of the upper interlayer dielectric layers 420, charge confinement feature layers 440 are positioned. As described above, the charge confinement feature layers 440 can be formed of a material that has an intrinsic negative charge, or fixed negative charge. In another embodiment, the charge confinement feature layers 440 can be formed of a material that is capable of trapping a negative charge during operation of the device. The charge confinement feature layers 440 can have etch selectivity with respect to the interlayer dielectric layers 420 and the sacrificial layers 430.

Referring to FIG. 17B, first line-type openings 452 are formed through the interlayer dielectric layers 410, the sacrificial layers 430, and the lower-most interlayer dielectric layer 410a in a vertical direction, and spaced apart in a horizontal direction, as shown. The first openings 452 expose upper portions of the underlying substrate 405 and extend in a first direction of horizontal extension.

Referring to FIG. 17C, a semiconductor liner layer 460 is formed on sidewalls and on a bottom of the first openings 452. An insulating layer 465 is then provided to fill the remainder of the first openings 452. The semiconductor liner layer will form the vertical pillars for the resulting device, and can be formed, for example, as a solid column that completely fills the openings 452.

A “macaroni”-type pillar is shown, including a cylindrical shell or walls of semiconductor material 460 surrounding an insulative, or hollow, core 465.

Referring to FIG. 17D, a plurality of second openings 467 extending in the first horizontal direction are formed between neighboring semiconductor liners 460. In one embodiment, the second openings 467 expose the lower-most interlayer dielectric layer 410a. This procedure permits access to a region where the control gates and floating gates of the resulting gate insulating layer 475 (see FIG. 17F below) of the memory device will be formed along sidewalls of the resulting semiconductor liner layers 460, eventually comprising the vertical pillars of the device.

Referring to FIG. 17E, the sacrificial layer patterns 430 including, for example, layers 431, 432, 433, 434, 435, and 436 are removed by a wet etching process. In a case where the lower-most interlayer dielectric layer 410a is formed of a same material as the sacrificial layer patterns 430, exposed portions of the lower-most interlayer dielectric layer 410a are likewise removed. In an example where the sacrificial layer patterns 430 are formed of silicon nitride, the etchant of the wet etching process can comprise an acid containing a phosphor atom such as hypophosphoric acid, phosphoric acid or phosphorous acid. Resulting concave openings 470 extend from the second opening 467 in the second horizontal direction of extension and lie adjacent the walls of the silicon semiconductor liners 460 to expose outer sidewalls thereof.

Referring to FIG. 17F, a gate insulating layer 475 is provided on the resulting structure. The gate insulating layer 475 covers interior walls of the concave openings 470, including covering the exposed outer sidewalls of the semiconductor liners 460. As described above, the gate insulating layer 475 can comprise a charge storage layer so that the device can operate as a non-volatile memory device. In some embodiments, and as shown in the close-up view of FIG. 18, the gate insulating layer 475 comprises a tunnel oxide layer 475a, a charge trapping layer 475b and a blocking insulating layer 475c that are sequentially formed in the second openings 467 and on lower, side, and upper walls of the concave openings 470. In one embodiment, the tunnel oxide layer 465a can be formed using a thermal oxidation process, which makes it more resistant to degradation over time, leading to improved device reliability and endurance.

In various embodiments, the charge trapping layer 475b can be a floating-gate structure, for example, comprising a poly-silicon material, or can comprise an ONO (oxide-nitride-oxide) structure. The blocking oxide layer 475c can comprise, for example, silicon oxide, or other suitable high-k oxide layer.

Referring to FIG. 17G, a gate conductive layer 480 formed of a conductive material is provided to fill the second openings 467, including the concave openings 440. In one embodiment, the conductive material comprises tungsten silicide.

Referring to FIG. 17H, the central portions of the gate conductive layer 480 are etched, forming third openings 485 that separate portions of the gate conductive layer 480 into gate patterns 500, including gate patterns 501, 502, 503, 504, 505 and 506. In one embodiment, the lower-most gate pattern 501 will become a lower select plate for the device, while gate patterns 502, 503, 504, and 505 will become word line plates for the device. The upper-most gate pattern 506 will become an upper select gate for the device. As a result of this processing step, lower-most gate pattern 501 can remain intact, or partially etched, in a case where the lower select plate operates as a select plate for all vertical pillars in the array.

Referring to FIG. 17I, the third openings 485 are filled with an insulative material to form an insulation pattern 490.

Referring to FIG. 17J, the semiconductor liners 460 and associated insulating layers 465 are pattered and etched to form fourth openings 497 that separate the liners 460 in the first horizontal direction into independent vertical pillars 460. The fourth openings 497 are then filled with an insulating material to electrically insulate the vertical pillars 460 in the first horizontal direction.

Referring to FIG. 17K, drain regions are formed at the tops of the pillars 460 using standard doping techniques. First conductive patterns 510 can then be formed and patterned to make electrical contact with the drain regions D of the tops of pillars 460 arranged in a second horizontal direction of extension of the device. In one embodiment, the conductive patterns comprise bitlines of the resulting device. The resulting device is known in the art as a vertical-cavity VNAND-type device.

Referring to the close-up view of FIG. 18, which is a close-up of region ‘A’ of FIG. 17K, it can be seen that the charge confinement features formed by layers 440 are positioned relative to the vertical channel 460 to operate in the manner described herein. In particular, the charge confinement features 440 limit the migration of charge stored in the charge trapping layer 475b to the vertical portion of the charge trapping layer 475b between the sidewall of the gate 500 and the vertical channel 460. The presence of the charge confinement features thus prevent the migration of charge present in the charge trapping layer 475b to the horizontal portions of the charge trapping layer 475b. Such migration of charge along the horizontal walls of the gate 500 would otherwise result in loss of information stored in the memory cell.

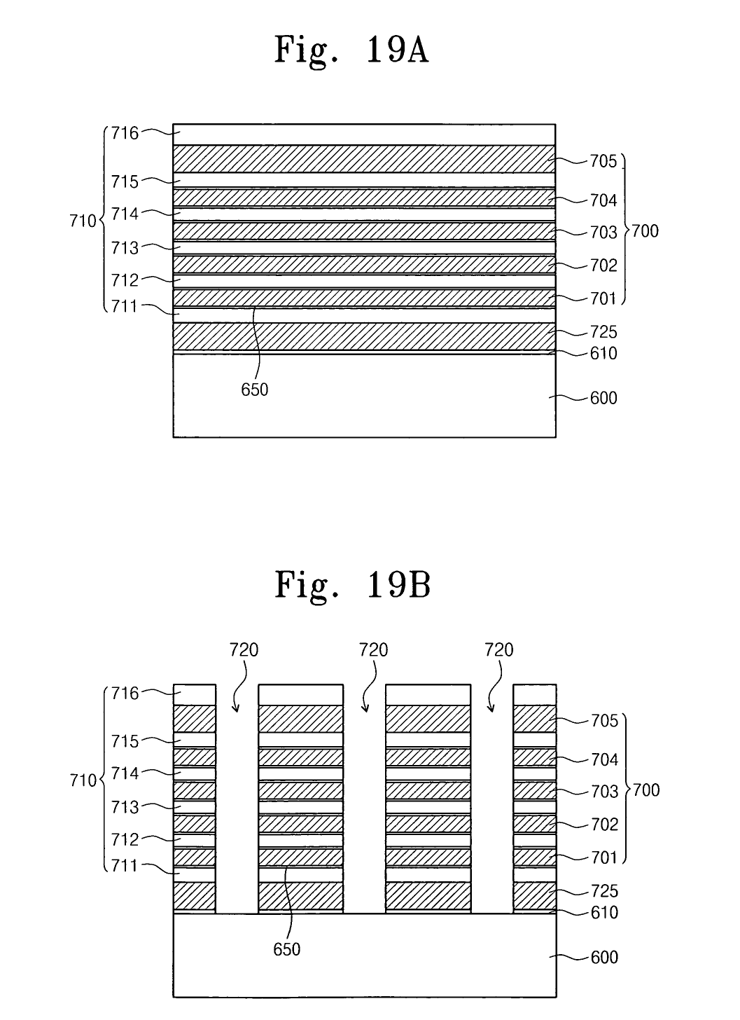

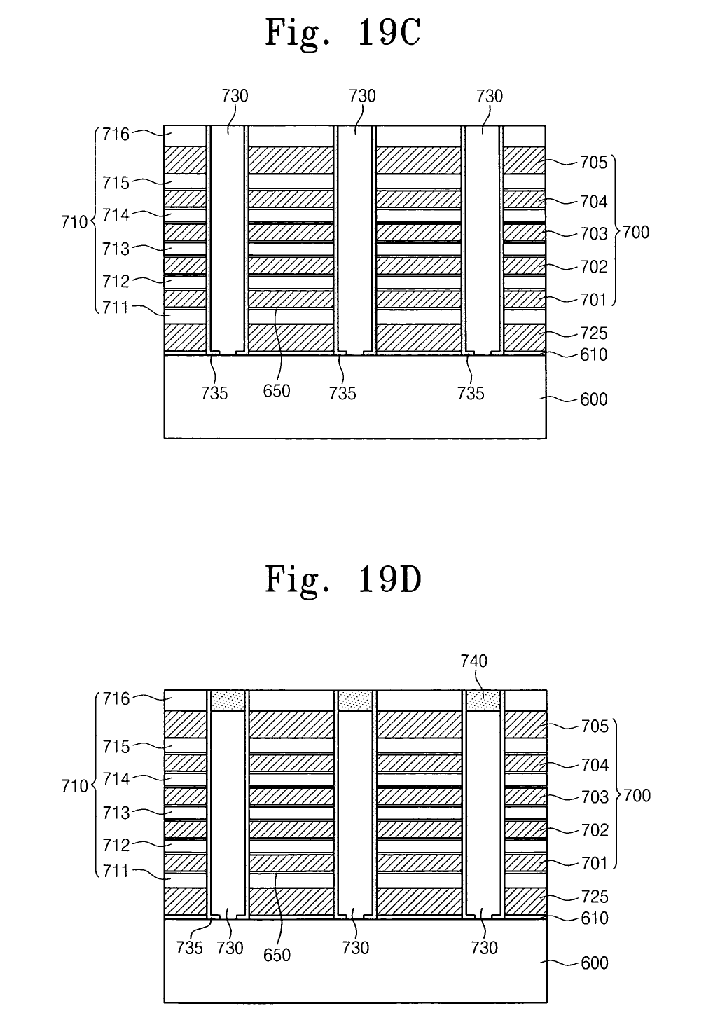

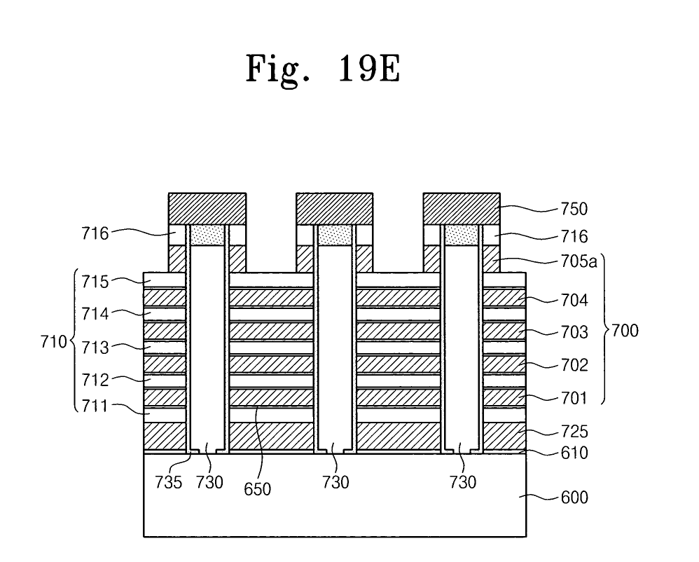

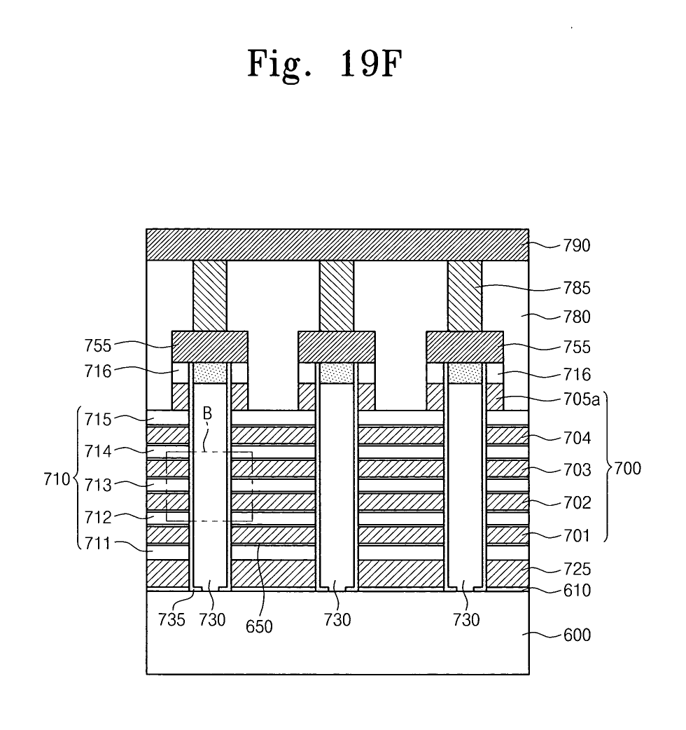

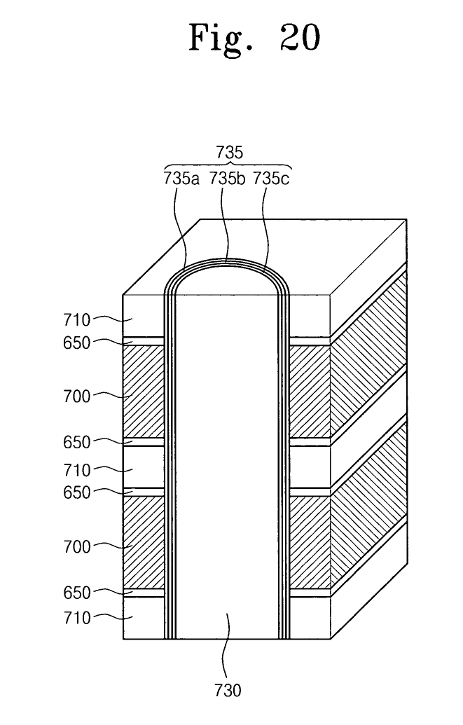

FIGS. 19A-19F are perspective views of a method of forming a vertical-channel memory device, in accordance with other embodiments of the present invention. FIG. 20 is a close-up view of memory cells in the vertical channel of the memory device formed according to FIGS. 19A-19F.

Referring to FIG. 19F and FIG. 20, one example embodiment of a vertical-channel memory device includes a number of vertical channels 730 of semiconductor material that are separated from one another. Neighboring memory cell gates 700, for example, formed of tungsten, are separated from each other in the vertical direction by isolation layers 710. Charge confinement features in the form of layers 650 are on opposed faces of the memory cell gates 700. In one example, the charge confinement features 750 comprise AlN. In other embodiments, the charge confinement features comprise other materials described herein as being suitable for charge confinement. Each vertical channel of semiconductor material 730 is surrounded by a tunnel oxide layer 735c, a charge trapping layer 735b and a blocking oxide layer 735a.

The charge confinement features 650 operate in the manner described herein to limit the migration of charge stored in the charge trapping layer 735b in a vertical direction between neighboring memory cells. Such migration of charge in a vertical direction between neighboring gates 500 would otherwise result in loss of information stored in the memory cell.

Referring to FIG. 19A, a substrate 600 is prepared. In one embodiment, the substrate 600 comprises a single-crystal semiconductor material substrate that provides a seed layer for later formation of single-crystal vertical pillars. In other embodiments, the substrate 600 can comprise a polycrystalline semiconductor material. A lower-most interlayer dielectric layer 610, also referred to herein as a lower gate insulator 610, is provided on the substrate. A first lower gate layer 725 is formed on the lower-most interlayer dielectric layer 610. The lower gate layer 725 may optionally be formed as a single gate layer or as multiple gate layers as shown. In a case where the lower gate layer 725 comprises multiple gate layers, the first lower gate layer 725 can comprise a polysilicon layer with an upper metal layer. In certain embodiments of the present invention, the lower-most interlayer dielectric layer 610 is sufficiently thin so that an inversion layer can be created in the underlying semiconductor material of the substrate 600 when a suitable voltage is applied to the gate layer 725.

Multiple alternating interlayer dielectric layers 710, including in this example, layers 711, 712, 713, 714, 715, and 716 and conductive gate layers 700, including in this example, layers 701, 702, 703, 704, and 705 are formed on the first lower gate pattern 725 on the resulting structure. In various embodiments, the interlayer dielectric layers 710 can comprise a material selected from the group consisting of oxide, HDP oxide, CVD oxide, PVD oxide, BPSG, SOG, mixtures thereof, and other suitable materials. The gate layers 700 can comprise a material selected from the group consisting of poly-Silicon, W, TaN, TiN, metal silicide, mixtures thereof, and other suitable materials.

Referring to FIG. 19B, the interlayer dielectric layers 710 and the conductive gate layers 700 are patterned to form vertical openings 720 in the memory cell region of the device. The lower-most interlayer dielectric layer 610 is also removed at a bottom of the vertical openings 720, exposing a top portion of the substrate 600 in each opening 720.

Referring to FIG. 19C, a gate insulating layer 735 is provided on the resulting structure. The gate insulating layer 735 covers a bottom and interior sidewalls of the vertical openings 720, and a top of the uppermost interlayer dielectric layer 716. In the embodiment shown, the exposed middle portion of the gate insulating layer 735 at the bottom of the openings 720 is removed using a spacer layer (not shown) as an etch mask, exposing the underlying substrate 600. Vertical pillars or vertical channels 730 are then formed in the openings 720. The pillars 730 can be formed of a semiconductor material such as poly-silicon, amorphous silicon, or single-crystal silicon.

FIG. 20 is a close-up perspective view of an embodiment of the gate insulating layer and pillar in the vertical openings 720. In one embodiment, the gate insulating layer 735 comprises a charge storage layer so that the device can operate as a non-volatile memory device. In the example of FIG. 20, the gate insulating layer 735 comprises a sequentially formed tunnel insulating layer 735c, a charge storage layer 735b, and a blocking insulating layer 735a. Gate insulating layers 735 formed according to this configuration are described in U.S. Pat. Nos. 6,858,906 and 7,253,467 and in United States Patent Application Publication No. 2006/0180851, the contents of each being incorporated herein by reference. In certain embodiments, the charge storage layer 735 can comprise a charge trapping layer. In various embodiment, the charge trapping layer can comprise SiN. Other suitable materials for the charge trapping layer can be employed, for example, Al₂O₃, HfAlOx, HfAlON, HfSiOx, HfSiON and multiple layers thereof. In another embodiment, the charge storage layer 735 can comprise a floating gate layer, comprising a conducting or semiconducting material

Referring again to FIG. 20, the vertical pillars 730 may be formed to completely fill the openings 720 so that the pillars are substantially solid, as shown in the embodiment of FIG. 20. Alternatively, the pillars may be formed as “macaroni-type” pillars, whereby the pillars are hollow in shape, with a hollow central region, or, alternatively, a central region that is formed of an insulative material. The sidewalls can be generally cylindrical or rectangular in cross-section shape, and can fully surround the central region, or can be spaced apart and lie at opposed sides of the central region. Other cross-sectional shapes for the sidewalls are possible and equally applicable.

Referring to FIG. 19D, additional patterning is performed to so that the conductive gate layers 700, including gate layers 701, 702, 703, 704, and 705 are patterned to form first through fourth word line plates and the upper select line. The gate layers 700 are patterned in a stair-type pattern at edges of the device, to provide vertical access to the plurality of gate layers 700. A source region S is then formed at the top surface of an exposed portion of the substrate. Drain regions D are formed at the tops of the pillars 730 using standard doping techniques.

Referring to FIG. 19E, a first conductive layer 750 is formed on, and in contact with, the drain regions D of the pillars 730. The first conductive layer 750, the uppermost interlayer dielectric layer 716 and the uppermost conductive gate layer 705 are then patterned to form upper select line patterns 705a that extend in the second horizontal direction.

Referring to FIG. 19F, the first conductive layer 730 is further patterned. A first upper interlayer dielectric layer 780 is then formed on the resulting structure, and contact plugs 785 are formed to make contact with the underlying conductive components. A second conductive layer is formed and patterned on the first upper interlayer dielectric layer 780 to form conductive lines 790 and features in contact with the underlying contact plugs 785. In the memory cell area of the device, conductive lines that connect to the drain regions D of vertical pillars that are arranged in the first horizontal direction provide bit lines BL of the device. The resulting device is known in the art as a vertical-cavity BICS-type device.

Referring to the close-up view of FIG. 20, which is a close-up of region ‘B’ of FIG. 19F, it can be seen that the charge confinement features formed by layers 650 are positioned relative to the vertical channel 730 to operate in the manner described herein. In particular, the charge confinement features 650 limit the migration of charge stored in the charge trapping layer 735b in a vertical direction parallel to the direction of extension of the vertical channel 730. Such migration of charge along the charge trapping layer 735 in the vertical direction would otherwise result in loss of information stored in the memory cell.

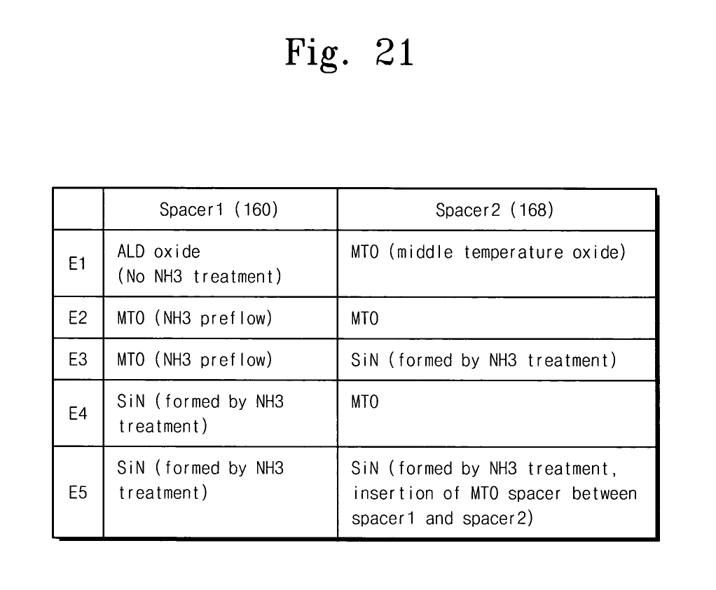

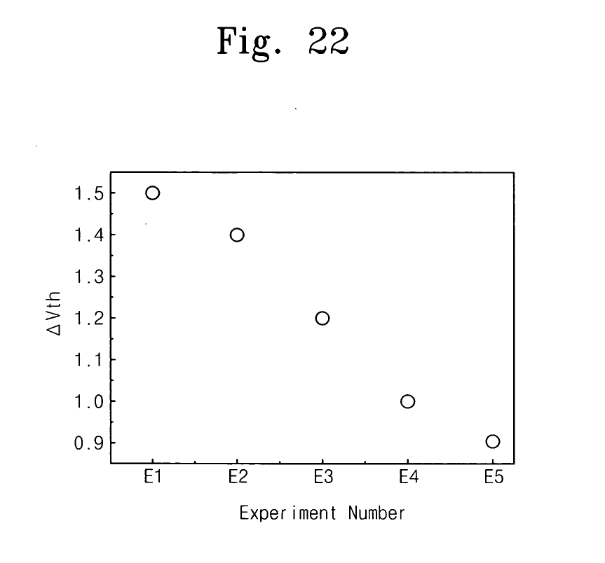

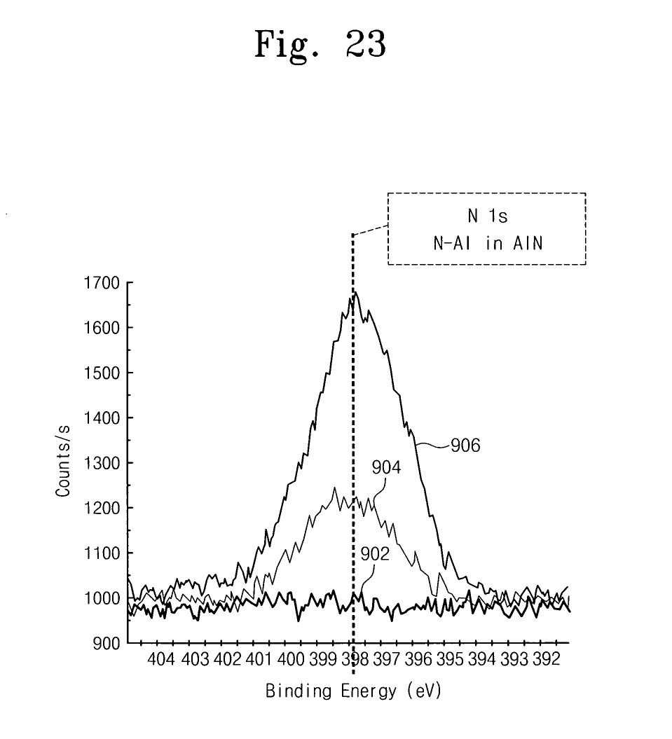

FIGS. 21 and 22 are charts illustrating experimental data collected on a sample embodiment. In the experiment, an experimental sample similar to the embodiment shown in FIG. 8 was prepared and tested.

The concept that the charge confinement features can block unwanted lateral charge spreading of the charge storage layer was tested and proved by combining different kinds of oxides/nitrides that contain varying amounts of NH₃, which leads to varying amounts of fixed charge. By increasing the amount of fixed charge, suppression of charge loss was demonstrated. Such charge loss was measured by monitoring shift in threshold voltage (ΔVₜₕ) of transistors prior to and following a baking treatment at 200° C. Testing at a high temperature is appropriate because charge loss is a thermally-activated process. When a flash memory cell is in a “write” state, a stored electron increases the threshold voltage of a cell transistor. When a cell loses its stored electron, the threshold voltage drops. Hence, a shift in threshold voltage following the baking treatment indicates the amount of stored charge that is lost.

In the experiment, three kinds of materials were used: ALD oxide which is not exposed to NH₃; MTO which is exposed to small amount of NH₃ preflow prior to deposition; and SiN that is exposed to a large amount of NH₃. The nitrogen content is greater in the increasing order of ALD oxide, MTO and SiN.

In an embodiment of the present invention, the agent for nitridation can comprise ammonia or primary amine such as methyl amine, ethyl amine or propyl amine. Ammonia derivative such as ammonium salt including NH4Cl should be regarded as an equivalent of ammonia.

Referring to FIG. 21 and FIG. 8, in a first experiment E1, the first sidewall spacer 160 at a sidewall of the gate was formed of ALD oxide that was not subjected to an NH₃ ammonianitridation process. Also, the second sidewall spacer 168 was formed of a mid-temperature oxide MTO which was exposed to small amount of NH₃ preflow prior to deposition. Referring to FIG. 22, it can be seen that the measured change in threshold voltage ΔVₜₕ for this embodiment was relatively high at 1.5V.

Referring to FIG. 21 and FIG. 8, in a second experiment E2, the first sidewall spacer 160 at a sidewall of the gate was formed of an MTO oxide which was exposed to a small amount of NH₃ preflow prior to deposition. Also, the second sidewall spacer 168 was formed of an MTO oxide. Referring to FIG. 22, it can be seen that the measured change in threshold voltage ΔVₜₕ for this embodiment was improved, relative to the first experiment, at 1.4V.

Referring to FIG. 21 and FIG. 8, in a third experiment E3, the first sidewall spacer 160 at a sidewall of the gate was formed of an MTO oxide that was subjected to an NH₃ nitridation process. Also, the second sidewall spacer 168 was formed of SiN, formed using an NH₃ nitridation treatment that is exposed to a large amount of NH₃. Referring to FIG. 22, it can be seen that the measured change in threshold voltage ΔVₜₕ for this embodiment was even further improved at 1.2V.

Referring to FIG. 21 and FIG. 8, in a fourth experiment E4, the first sidewall spacer 160 at a sidewall of the gate was formed SiN, formed using an NH₃ nitridation. Also, the second sidewall spacer 168 was formed of an MTO oxide. Referring to FIG. 22, it can be seen that the measured change in threshold voltage ΔVₜₕ for this embodiment was even further improved at 1.0V.

Referring to FIG. 21 and FIG. 8, in a fifth experiment E5, the first sidewall spacer 160 at a sidewall of the gate was formed SiN, formed using an NH₃ nitridation. Also, the second sidewall spacer 168 was formed of SiN, formed using an NH₃ nitridation treatment. Referring to FIG. 22, it can be seen that the measured change in threshold voltage ΔVₜₕ, for this embodiment was even further improved at 0.9V.

From the above experimental data, it can be seen that the experiment demonstrated that with increased nitridation of the sidewall spacers, and thus with increased presence and density of the confinement features 136, a reduction in the measured change in threshold voltage ΔVₜₕ, in the resulting device occurs which indicates a reduction in the lateral spreading of stored charge.

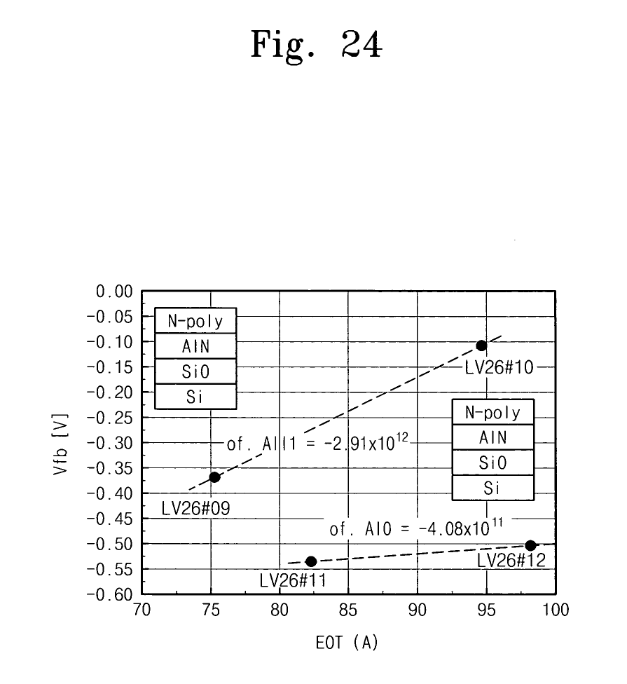

FIGS. 23 and 24 are charts further illustrating experimental data collected on a sample embodiment. In the experiment, an experimental sample similar to the embodiment shown in FIG. 8 was prepared and tested.

Referring to FIG. 23, a sample was tested and measured, to determine the effectiveness of a nitridation process imparted on an Al₂O₃ sample. In FIG. 22, the abscissa of the chart represents the binding energy, and the ordinate represents counts per second measured using x-ray photoelectron spectroscopy. It can be seen that the sample initially has generally minimal nitride content initially at graph 902. When subjected to a nitridation treatment, using ammonia, it can be seen that the nitride content increases at graph 904. When subjected to further nitridation treatment, using ammonia, it can be seen that the nitride content further increases at graph 906. Also, when the thus-nitrided material is subjected to re-oxidation, it can be converted back to exhibit the properties of the state of graph 902, where the nitride peak in graph 906 is removed.

Referring to FIG. 24, a sample was prepared to measure the amount of fixed charge for AlN and Al2O3. Capacitor stacks were formed of either poly/AlN/SiO2/Si (substrate), or poly/Al2O3/SiO2/Si (substrate). The amount of fixed charge can be measured from a typical capacitance-voltage (C-V) plot (not shown). Capacitance is inversely proportional to the effective thickness of oxide (EOT), provided other conditions being equal; and such capacitance is proportional to fixed charge, which is proportional to flat-band voltage (V_{fb}). Hence, from the slope of V_{fb} vs. EOT, the amount of fixed charge (Q) can be extracted.

Depending on the content of nitrogen of AlON or SiON, silicon oxynitride or metal oxynitride material can operate as a charge confinement feature. The greater the content of nitrogen, the more effective the charge confinement feature is in preventing charge spreading. The content of nitrogen is more than 0.7 atomic % based on the total numbers of nitrogen and oxygen atoms.

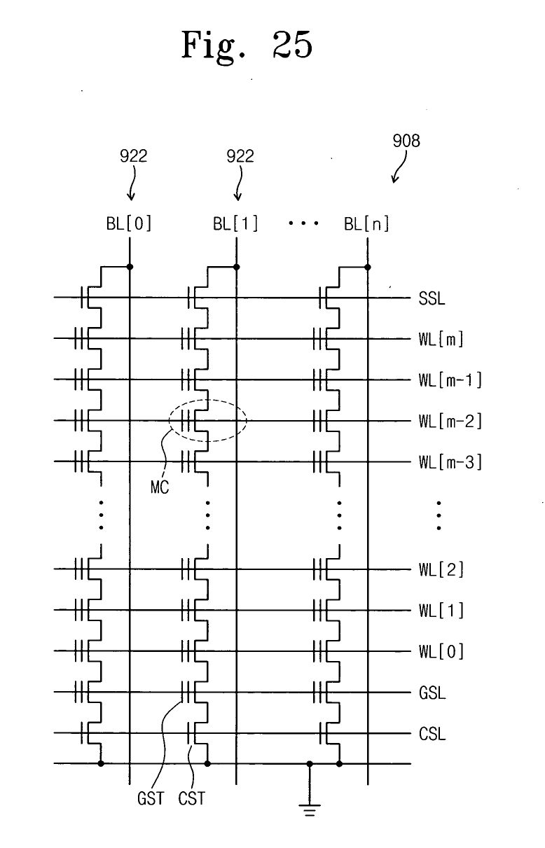

FIG. 25 is a circuit diagram of a non-volatile memory device including a memory cell array that includes memory cells configured according to the embodiments described herein. Referring to FIG. 25, a memory cell array 908 includes a plurality of memory cells MC arranged in rows and columns. In each column, a plurality of memory cells MC are arranged in series between a string select transistor SST and a ground select transistor GST. Together, the plurality of memory cells MC, the string select transistor SST and the ground select transistor GST connected in series combine to form a cell string 922. A plurality of the cell strings 922 are similarly arranged between bit lines BL[0], BL[1], . . . BL[n] and a common source line CSL. In this embodiment, the common source line CSL is connected to each of the common source transistors CST, and gates of corresponding ground select transistors GST are connected to a ground select line GSL of the device. Gates of corresponding string select transistors SST are connected to a string select line SSL of the device. Control gates of corresponding memory cell transistors MC of different cell strings 922 are connected to a word line WL[0] . . . WL[m] of the device. In this example, the reference letter “m” refers to the number of memory cell transistors MC[m] in each cell string 922, and the reference letter “n” refers to the number of cell strings 922 in the memory cell block of the memory cell array 908.

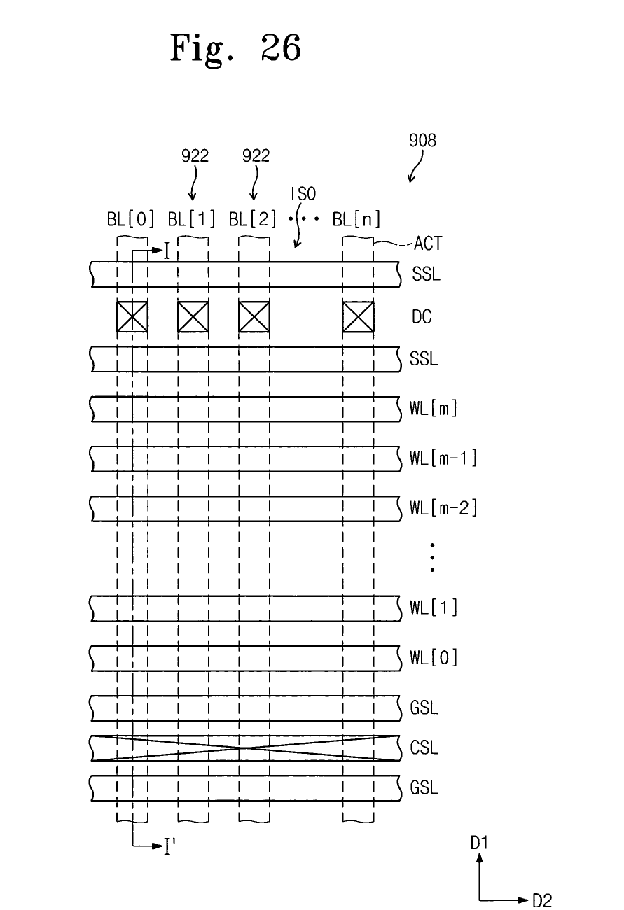

FIG. 26 is a top plan view of a memory cell array 908, in accordance with embodiments of the present invention. In this view, it can be seen that the string select line SSL, word lines WL[m], and ground select line GSL correspond to string select transistors SST, memory cell transistors MC and ground select transistors GST arranged in series between a bit line BL and a common source line CSL. An active region ACT of each cell string 922 extends in a first direction of extension D1 in a column direction of the device between the bit line contact BC and the common source line CSL. Neighboring active regions ACT are separated from each other by isolation regions ISO. The string select line SSL, word lines WL[m], and ground select line GSL extend in a second direction of extension D2, in a row direction of the device.

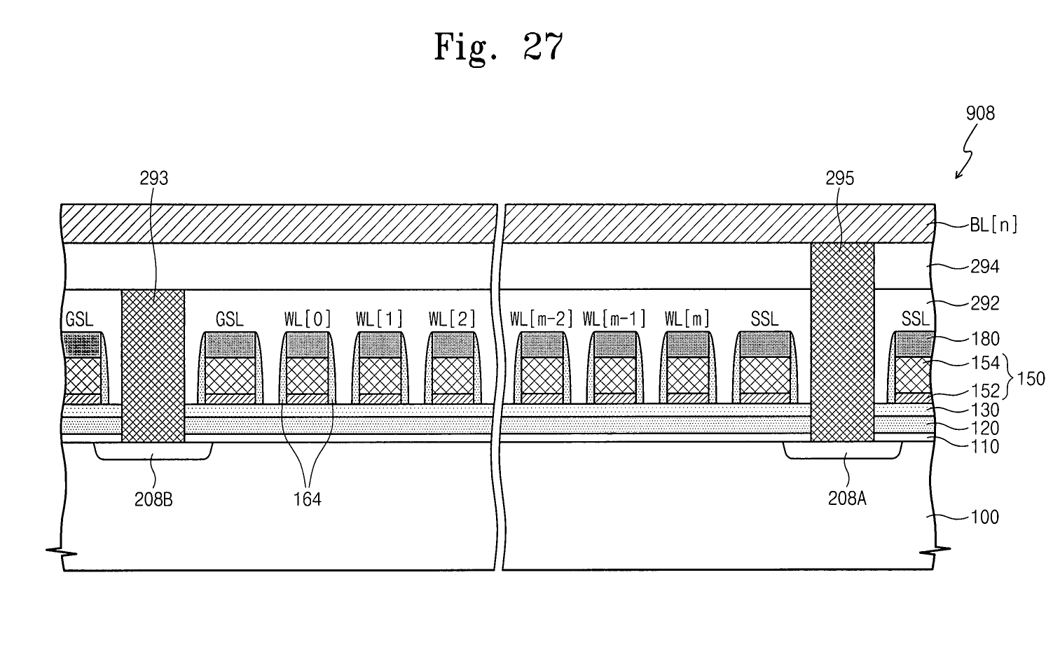

FIG. 27 is a cross-sectional diagram of a cell string 922 of the memory cell array 908 of FIG. 26, taken along section line I-I′ in accordance with an embodiment of the present invention. In this view, it can be seen that the memory cells of each cell string 922 of the device include charge confinement features 164 positioned at sidewalls of the gate structure 151 and on the blocking layer 130 of the type shown and described in connection with FIG. 3 above. Insulative layers 292 and 294 are provided on the memory cells between the substrate 100 and the bit line BL[n]. The bit line BL[n] is connected to the first substrate impurity region 208b by direct connect plug 295, and the common source line is connected to the second substrate impurity region 208b by plug 293.

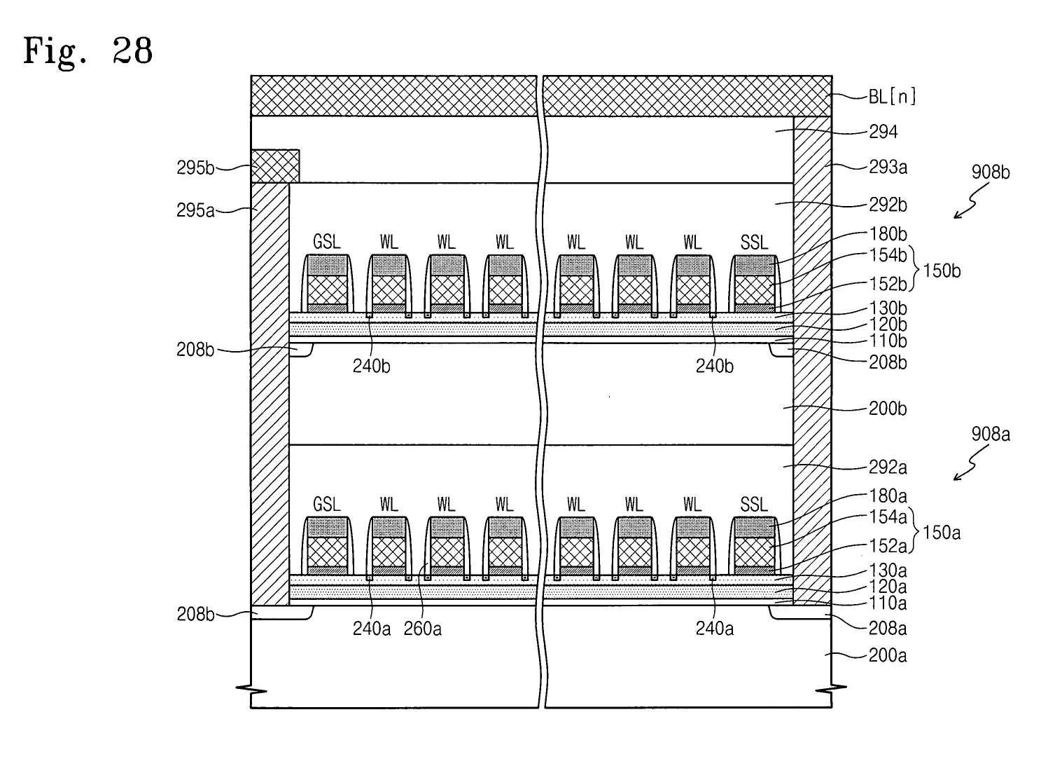

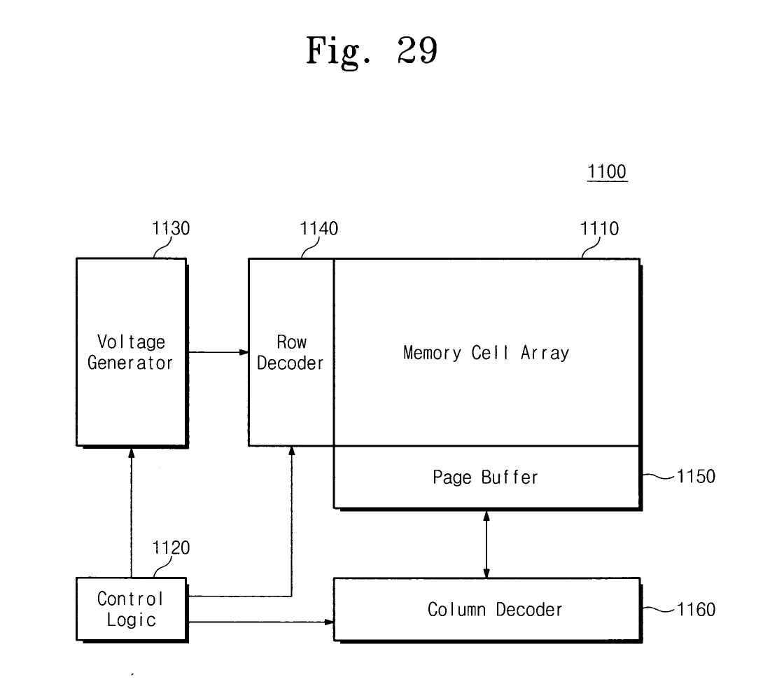

FIG. 28 is a cross-sectional diagram of a stacked memory cell array in accordance with embodiments of the present invention. In this example, embodiment, multiple horizontally configured memory cell devices are stacked in a vertical direction, on top of each other. Elements of a cell string of the first layer are represented by reference letter “a”, while elements of a cell string of the second layer are represented by reference letter “b”, The bit line BL[n] is connected to the first substrate impurity region of the first layer 208a and of the second layer 208b by direct connect plug 293c, and the common source line 295b is connected to the second substrate impurity region of the first layer 108b and of the second layer 108b by plug 295a. In this view, it can be seen that the memory cells of each cell string 922a, 922b of the device include charge confinement features 240a, 240b positioned below sidewall spacers of the memory cell gates in the blocking oxide layers 130a, 130b of the type shown and described in connection with FIG. 1 above.

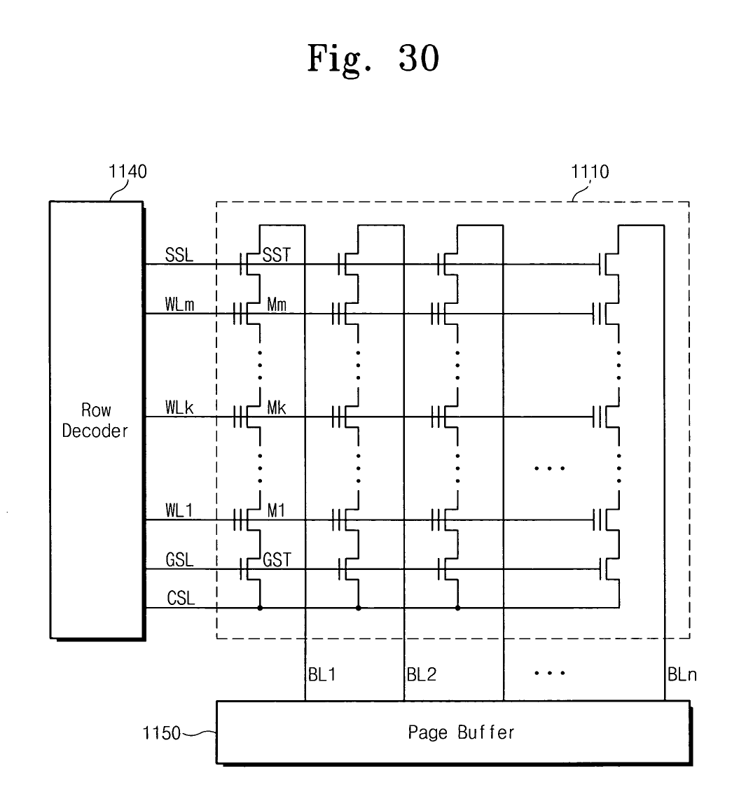

FIG. 29 is a block diagram of a memory device in accordance with embodiments of the present invention. A memory device 1100 includes a memory cell array 1110, control logic 1120, a voltage generator 1130, a row decoder 1140, a page buffer 1150, and a column decoder 1160. The memory cell array 1110 includes a plurality of memory cell strings including memory cells of the type described herein, optionally arranged in memory blocks. Control logic 1120 transmits control signals to the voltage generator 1130, the row decoder 1140 and the column decoder 1160 in accordance with the operation to be performed, for example, erase, programming, and read operations. The voltage generator 1130 generates the voltages such as Vpass, Vread, Verase, Vstep voltages required for performing the device operations. The row decoder 1140 determines the manner in which the voltage signals provided by the voltage generator are applied to the lines, such as string select lines SSL, word lines WLk, ground select lines GSL, and common source lines of the memory cell array 1110. The column decoder determines which signals of the bit lines BLn of the device read by the page buffer 1150 are to be used in determining data values that are read, or determines voltages that are applied to the bit lines BLn during programming and erase operations.

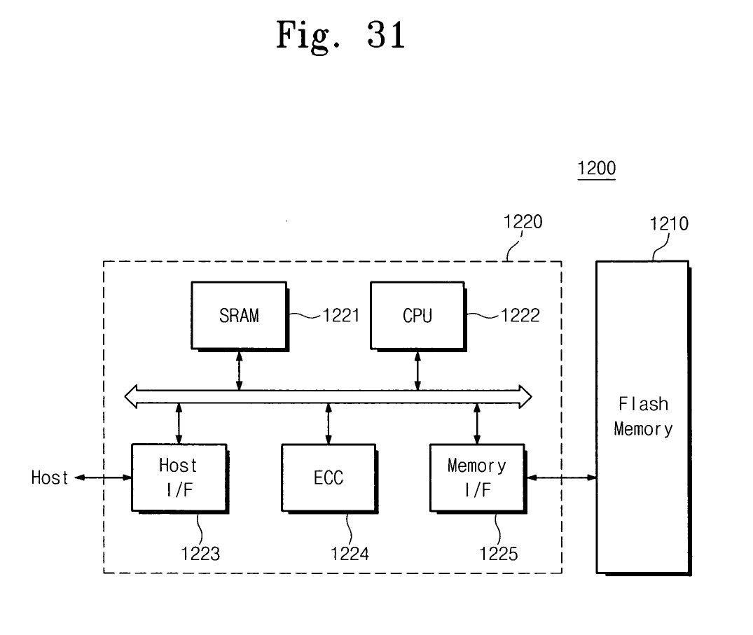

FIG. 30 is a block diagram of the memory cell array 1110, of the memory device 1100 of FIG. 29, in accordance with embodiments of the present invention. In this figure it can be seen that the row decoder 1140 applies the various voltage levels to the one of or more string select lines SSL, the word lines WLk, the ground select line GSL, and the common source line CSL. The page buffer 1150 is connected to the bit lines BLn of the device 1110.

FIG. 31 is a block diagram of a memory card that includes a semiconductor device in accordance with the embodiments of the present invention. The memory card 1200 includes a memory controller 1220 that generates command and address signals C/A and a memory module 1210 for example, flash memory 1210 that includes one or a plurality of flash memory devices. The memory controller 1220 includes a host interface 1223 that transmits and receives command and address signals to and from a host, a controller 1224, and a memory interface 1225 that in turn transmits and receives the command and address signals to and from the memory module 1210. The host interface 1223, the controller 1224 and memory interface 1225 communicate with controller memory 1221 and processor 1222 via a common bus.

The memory module 1210 receives the command and address signals C/A from the memory controller 1220, and, in response, stores and retrieves data DATA I/O to and from at least one of the memory devices on the memory module 1210. Each memory device includes a plurality of addressable memory cells and a decoder that receives the receives the command and address signals, and that generates a row signal and a column signal for accessing at least one of the addressable memory cells during programming and read operations.

Each of the components of the memory card 1200, including the memory controller 1220, electronics 1221, 1222, 1223, 1224, and 1225 included on the memory controller 1220 and the memory module 1210 can employ memory devices including memory cells configured according to the inventive concepts disclosed herein.

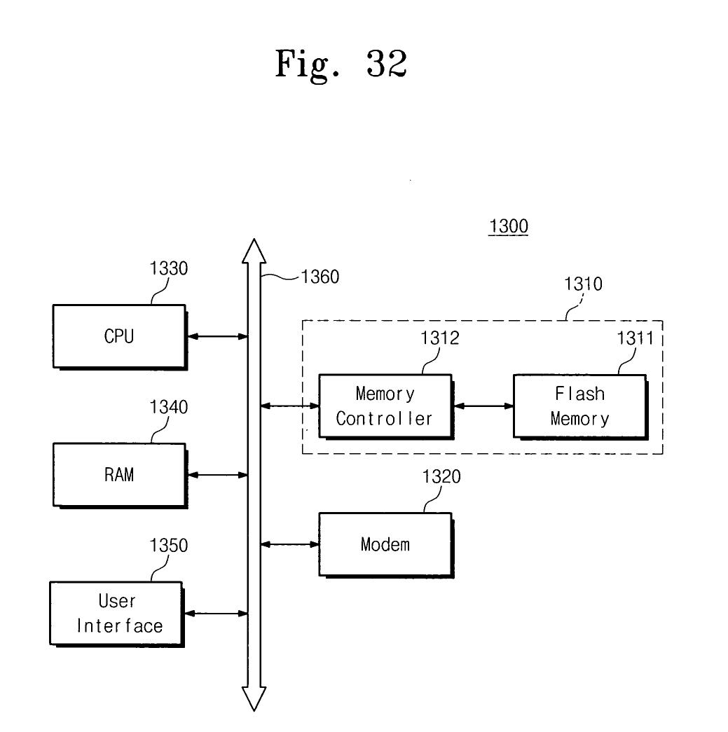

FIG. 32 is a block diagram of a memory system 1300 that employs a memory module 1310, for example, of the type described herein, in accordance with the embodiments of the present invention. The memory system 1300 includes a processor 1330, random access memory 1340, user interface 1350 and modem 1320 that communicate via a common bus 1360. The devices on the bus 1360 transmit signals to and receive signals from the memory card 1310 via the bus 1360. Each of the components of the memory system 1300, including the processor 1330, random access memory 1340, user interface 1350 and modem 1320 along with the memory card 1310 can employ memory devices including memory cells of the type disclosed herein. The memory system 1300 can find application in any of a number of electronic applications, for example, those found in consumer electronic devices such as solid state disks (SSD), camera image sensors (CIS) and computer application chip sets.

The memory systems and devices disclosed herein can be packaged in any of a number of device package types, including, but not limited to, ball grid arrays (BGA), chip scale packages (CSP), plastic leaded chip carrier (PLCC) plastic dual in-line package (PDIP), multi-chip package (MCP), wafer-level fabricated package (WFP), and wafer-level processed stock package (WSP).

While embodiments of the invention have been particularly shown and described with references to preferred embodiments thereof, it will be understood by those skilled in the art that various changes in form and details may be made herein without departing from the spirit and scope of the invention as defined by the appended claims.

1.-15. (canceled)

16. A memory device comprising:
a first memory cell and a second memory cell on a common body of semiconductor material, the first and second memory cells each comprising:
a tunnel oxide layer on the body;
a charge trapping layer on the tunnel oxide layer,
a blocking layer on the charge trapping layer; and
a control gate on the blocking layer;
wherein the control gate of the first memory cell and the control gate of the second memory cell have facing opposed sidewalls; and
a charge confinement feature on the charge trapping layer having a horizontal position that is between horizontal positions of the opposed sidewalls of the control gates, the charge confinement feature limiting migration of charge present in the charge trapping layer.

17. The memory device of claim 17 wherein the charge confinement feature is further on the charge trapping layer.

18. The memory device of claim 17 wherein the charge confinement feature comprises a material that contains negative charge.

19. The memory device of claim 18 wherein the material comprises metal nitride.

20. The memory device of claim 19, wherein the material comprises aluminum nitride or aluminum oxynitride whose nitrogen content is richer than oxygen.

21. The memory device of claim 20 wherein the charge confinement feature comprises a charge trapping material that can trap negative charge.

22. The memory device of claim 21 wherein the charge trapping material comprises silicon nitride or silicon oxynitride whose nitrogen content is richer than oxygen.

23. The memory device of claim 17 wherein the charge confinement feature is further on the charge trapping layer and is positioned in the blocking layer, the charge confinement feature having sidewalls that are in contact with the blocking layer.

24. The memory device of claim 17 wherein the charge confinement feature comprises multiple charge confinement features positioned in the blocking layer, the charge confinement features having inner sidewalls that are in contact with the blocking layer and having sidewalls that are not in contact with the blocking layer.

25. The memory device of claim 17 further comprising insulative sidewall spacers at the sidewalls of the control gates of the first and second memory cells, wherein the charge confinement feature comprises at least one charge confinement feature further on the charge trapping layer and positioned in the blocking layer below the sidewall spacers.

26. The memory device of claim 17 wherein the charge confinement feature comprises sidewall spacers at the sidewalls of the control gates of the first and second memory cells and on the blocking layer.

27. The memory device of claim 17 wherein the charge confinement feature is further on the charge trapping layer and comprises a charge confinement layer pattern positioned adjacent the first and second sidewalls of the control gates of the first and second memory cells and on the blocking layer.

28. The memory device of claim 17 wherein the charge confinement feature comprises a film that covers the blocking layer and the facing opposed sidewalls of the first and second memory cells.

29. The memory device of claim 17 further comprising insulative sidewall spacers at the sidewalls of the control gates of the first and second memory cells, wherein the charge confinement features are further on the charge trapping layer and positioned on the blocking layer at a horizontal position that is adjacent a horizontal position of the sidewall spacers.

30. A semiconductor device comprising:
a stack comprising a first conductive layer, a second conductive layer on the first conductive layer and a insulation layer between the first and the second conductive layers on an active body of semiconductor material;
a memory cell structure including a vertical active region and a plurality of memory cells having memory storage units;
wherein the vertical active region is positioned vertically relative to the first and second conductive layers and electrically connected to the active body of semiconductor material; and
conductive lines connecting the memory cell structures to peripheral circuitry,
wherein a layer comprised of a charge confinement material is further disposed between the first and the second conductive layers.

31. The semiconductor device of claim 30, wherein the layer comprised of the charge confinement material further covers the lateral surface that contacts the vertical active channel.

32. The semiconductor device of claim 30 wherein the active body of semiconductor is on a stack comprising transistors that electrically connect and control the memory cell structure.

33.-38. (canceled)
